(19) United States
(12) Patent Application Publication
(10) Pub. No.: US 2026/0271527 A1
(43) Pub. Date: Sep. 10, 2026

(54) DISPLAY PANEL AND DISPLAY DEVICE

(71) Applicants: BEIJING BOE TECHNOLOGY DEVELOPMENT CO., LTD., Beijing (CN); BOE Technology Group Co., Ltd., Beijing (CN)

(72) Inventors: Dacheng Zhang, Beijing (CN); Chen Xu, Beijing (CN); Chao Pu, Beijing (CN)

(73) Assignees: BEIJING BOE TECHNOLOGY DEVELOPMENT CO., LTD., Beijing (CN); BOE Technology Group Co., Ltd., Beijing (CN)

(21) Appl. No.: 18/842,231

(22) PCT Filed: Nov. 7, 2023
(86) PCT No.: PCT/CN2023/130116

§ 371 Date: Aug. 28, 2024

(51) Int. Cl. H10K 59/122; H10K 59/126; H10K 59/131; H10K 59/35; H10K 59/38

(52) U.S. Cl. CPC H10K 59/122; H10K 59/126; H10K 59/131; H10K 59/352; H10K 59/38

(57) ABSTRACT

A display panel and a display device are provided. The display panel includes a plurality of sub-pixels, each sub-pixel includes a pixel definition layer, a first electrode and one or more light emitting functional layers. The pixel definition layer includes a pixel opening including one or more first grooves, the first electrode is arranged between the pixel definition layer and the driving substrate; a part of a surface of the light emitting functional layers arranged in the first grooves includes a first cambered surface, which includes a middle region and an edge region surrounding the middle region, a distance between a part of the first cambered surface in the middle region and the driving substrate is greater than a distance between a part of the first cambered surface in the edge region and the driving substrate in a direction perpendicular to a plane where the driving substrate is located.

### FIELD

The present disclosure relates to the field of display technologies, and more particularly to a display panel and a display device.

### BACKGROUND

With the rapid development of various display technologies, customers have higher and higher requirements for the performance of display panels, and display products are developing towards ultra-high pixels per inch (PPI) and ultra-high brightness.

In order to improve the brightness of the display panels, microlenses are usually arranged on a light emitting side of sub-pixels in the display panels. However, during the process of manufacturing the microlenses, the thermal reflux heating process will damage light emitting functional layers of the sub-pixels in the display panels, thereby reducing the display effect and the service life of the display panels. At present, there is an urgent need for a new microlens design.

### SUMMARY

Embodiments of the present disclosure adopt the following technical solutions.

In a first aspect, the embodiments of the present disclosure provide a display panel, including a driving substrate and a plurality of sub-pixels arranged in an array on the driving substrate, wherein each of the plurality of sub-pixels includes:
a pixel definition layer including a pixel opening, wherein the pixel opening includes one or more first grooves;
a first electrode arranged between the pixel definition layer and the driving substrate, wherein a partial region of the first electrode serves as a bottom of the pixel opening; and
one or more light emitting functional layers at least arranged in the first grooves, wherein a part of a surface of the light emitting functional layers on a side away from the driving substrate located in the first grooves includes a first cambered surface,
wherein the first groove includes a middle region and an edge region surrounding the middle region, and in the first groove, a distance between a part of the first cambered surface located in the middle region and the driving substrate is greater than a distance between a part of the first cambered surface located in the edge region and the driving substrate in a direction perpendicular to a plane where the driving substrate is located.

In the display panel provided by one or more embodiments of the present disclosure, a ratio between a depth of the pixel opening in the direction perpendicular to the plane where the driving substrate is located and a maximum size of the pixel opening in a direction parallel to the plane where the driving substrate is located is greater than or equal to 0:3.

In the display panel provided by one or more embodiments of the present disclosure, the ratio between the depth of the pixel opening in the direction perpendicular to the plane where the driving substrate is located and the maximum size of the pixel opening in the direction parallel to the plane where the driving substrate is located is greater than or equal to 0.3 and less than or equal to 0.8.

In the display panel provided by one or more embodiments of the present disclosure, the pixel opening includes one of the first grooves, and a maximum size of the sub-pixel in the direction parallel to the plane where the driving substrate is located is less than or equal to 2 μm.

In the display panel provided by one or more embodiments of the present disclosure, the pixel opening includes two or more of the first grooves, and a maximum size of the sub-pixel in the direction parallel to the plane where the driving substrate is located is less than or equal to 2 μm.

In the display panel provided by one or more embodiments of the present disclosure, the pixel opening further includes one or more spacers located between adjacent two of the first grooves, and a ratio between a depth of the first groove in the direction perpendicular to the plane where the driving substrate is located and a maximum size of the first groove in the direction parallel to the plane where the driving substrate is located is greater than or equal to 0.3 and less than or equal to 0.8.

In the display panel provided by one or more embodiments of the present disclosure, the ratio between the depth of the pixel opening in the direction perpendicular to the plane where the driving substrate is located and the maximum size of the pixel opening in the direction parallel to the plane where the driving substrate is located is greater than the ratio between the depth of the first groove in the direction perpendicular to the plane where the driving substrate is located and a maximum size of the first groove in the direction parallel to the plane where the driving substrate is located.

In the display panel provided by one or more embodiments of the present disclosure, the spacers and the pixel definition layer are arranged in the same layer.

In the display panel provided by one or more embodiments of the present disclosure, the spacers and the first electrode are an integrated structure.

In the display panel provided by one or more embodiments of the present disclosure, the first electrode includes a plurality of contact portions and a plurality of protrusion portions, wherein one of the plurality of protrusion portions is arranged between adjacent two of the plurality of contact portions, the plurality of contact portions serve as a plurality of bottoms of the first grooves and the plurality of protrusion portions serve as the spacers.

In the display panel provided by one or more embodiments of the present disclosure, the driving substrate includes a plurality of columnar connection electrodes, and one or more of the plurality of columnar connection electrodes are in contact connection with the first electrode in the sub-pixel; and
an orthographic projection of the columnar connection electrodes on a substrate of the driving substrate is located within an orthographic projection of the plurality of protrusion portions on the substrate; and an end of the columnar connection electrodes away from the substrate protrudes from a surface of the driving substrate near the first electrode.

In the display panel provided by one or more embodiments of the present disclosure, one or more fractures are arranged on the spacers, and one or more light emitting functional layers in adjacent two first grooves are communicated at positions of the fractures.

In the display panel provided by one or more embodiments of the present disclosure, a depth of the fractures in the direction perpendicular to the plane where the driving substrate is located is less than or equal to a height of the spacers in the direction perpendicular to the plane where the driving substrate is located.

In the display panel provided by one or more embodiments of the present disclosure, a region surrounded by an orthographic projection of an outer contour of at least one of the fractures on the substrate overlaps with the orthographic projection of the columnar connection electrodes on the substrate.

In the display panel provided by one or more embodiments of the present disclosure, a plurality of fractures are symmetrically distributed about a center of the sub-pixel.

In the display panel provided by one or more embodiments of the present disclosure, orthographic projection patterns of the spacers on the driving substrate include a ring shape or a grid shape.

In the display panel provided by one or more embodiments of the present disclosure, the light emitting functional layer includes a plurality of light emitting functional sublayers sequentially arranged in a direction away from the driving substrate, and a curvature of surfaces of the plurality of light emitting functional sublayers on the side away from the driving substrate gradually decreases in a direction away from the first electrode.

In the display panel provided by one or more embodiments of the present disclosure, the sub-pixel includes a second electrode covering the light emitting functional layer, and an average curvature of the second electrode is less than an average curvature of the light emitting functional layer, and a refractive index of the second electrode is less than a refractive index of the light emitting functional layer.

In the display panel provided by one or more embodiments of the present disclosure, in the first groove, a partial region of the surface of the light emitting functional layer on the side away from the driving substrate is parallel to a surface of the first electrode on the side away from the driving substrate; and

a ratio of an area of a part of the surface of the light emitting functional layer on the side away from the driving substrate that is parallel to a surface of the first electrode on the side away from the driving substrate to an area of the surface of the light emitting functional layer on the side away from the driving substrate is less than or equal to 20%.

In the display panel provided by one or more embodiments of the present disclosure, a ratio between a size of the pixel opening in a direction parallel to the plane where the driving substrate is located and a distance between adjacent two first electrodes in the same direction has a range of 0.7 to 1.4.

In the display panel provided by one or more embodiments of the present disclosure, a surface of the first electrode on the side away from the driving substrate includes one or more second cambered surfaces, wherein an orthographic projection of the first cambered surface on a substrate of the driving substrate is located within an orthographic projection of the second cambered surfaces on the substrate, and an orientation of the first cambered surface and an orientation of the second cambered surface are opposite.

In the display panel provided by one or more embodiments of the present disclosure, the second cambered surface serves as a bottom of the pixel opening, an area of a region surrounded by an orthographic projection of an outer contour of the second cambered surface on the driving substrate is greater than an area of a region surrounded by an orthographic projection of an outer contour of edges of the pixel opening on the driving substrate, and sidewalls of the pixel opening are provided with undercuts at positions proximate to the second cambered surface.

In the display panel provided by one or more embodiments of the present disclosure, a curvature of the second cambered surface is less than a curvature of the first cambered surface.

In the display panel provided by one or more embodiments of the present disclosure, the pixel definition layer includes the plurality of pixel openings and one or more pixel recessed portions located between adjacent two of the plurality of pixel openings;
each of the pixel recessed portions is provided with a second groove, wherein a region surrounded by an orthographic projection of an outer contour of the second groove on the driving substrate falls into a region surrounded by an orthographic projection of an outer contour of a gap between adjacent two first electrodes on the driving substrate; and
a ratio between a maximum size of the second groove in a direction parallel to the plane where the driving substrate is located and a depth of the second groove in a direction perpendicular to the plane where the driving substrate is located is less than or equal to a ratio between a maximum size of the first groove in a direction parallel to the plane where the driving substrate is located and a depth of the first groove in a direction perpendicular to the plane where the driving substrate is located.

In the display panel provided by one or more embodiments of the present disclosure, the second groove divides the same pixel recessed portion into two parts; and
a ratio between a size of a part of the pixel recessed portion and a size of the second groove has a range of 0.7 to 1.4 in the same direction parallel to the plane where the driving substrate is located.

In the display panel provided by one or more embodiments of the present disclosure, an absolute value of a difference between a ratio between the size of the part of the pixel recessed portion in the direction parallel to the plane where the driving substrate is located and a size of the second groove in the same direction and a ratio between a size of the pixel opening in the direction parallel to the plane where the driving substrate is located and a distance between adjacent two first electrodes in the same direction is less than or equal to 0.1.

In the display panel provided by one or more embodiments of the present disclosure, an absolute value of a size difference between adjacent two gaps is less than an absolute value of a size difference between two parts on the same pixel recessed portion in the same direction parallel to the plane where the driving substrate is located.

In the display panel provided by one or more embodiments of the present disclosure, the plurality of sub-pixels include a first sub-pixel, a second sub-pixel and a third sub-pixel, and display colors of the first sub-pixel, the second sub-pixel and the third sub-pixel are different;
in the direction parallel to the plane where the driving substrate is located, an absolute value of a size difference between a gap between the first sub-pixel and the second sub-pixel and a gap between the second sub-pixel and the third sub-pixel is less than an absolute value of a size difference between a second groove between the first sub-pixel and the second sub-pixel and a second groove between the second sub-pixel and the third sub-pixel; and
an absolute value of a size difference between a gap between the second sub-pixel and the third sub-pixel and a gap between the third sub-pixel and the first sub-pixel is less than an absolute value of a size difference between the second groove between the second sub-pixel and the third sub-pixel and a second groove between the third sub-pixel and the first sub-pixel.

In the display panel provided by one or more embodiments of the present disclosure; in the direction parallel to the plane where the driving substrate is located, the absolute value of the size difference between the gap between the first sub-pixel and the second sub-pixel and the gap between the second sub-pixel and the third sub-pixel is less than an absolute value of a size difference between a pixel recessed portion between the first sub-pixel and the second sub-pixel and a pixel recessed portion between the second sub-pixel and the third sub-pixel; and
the absolute value of the size difference between the gap between the second sub-pixel and the third sub-pixel and the gap between the third sub-pixel and the first sub-pixel is less than an absolute value of a size difference between the pixel recessed portion between the second sub-pixel and the third sub-pixel and a pixel recessed portion between the third sub-pixel and the first sub-pixel.

In the display panel provided by one or more embodiments of the present disclosure, a partial region of the light emitting functional layer is arranged in the second groove and on a surface of the pixel recessed portion on a side away from the driving substrate, and a part of the surface of the light emitting functional layer on the side away from the driving substrate located in the second groove includes a third cambered surface, and a curvature of the first cambered surfaces is less than a curvature of the third cambered surface.

In the display panel provided by one or more embodiments of the present disclosure, the curvature of the first cambered surface is greater than the curvature of the part of the surface of the light emitting functional layer away from the driving substrate arranged in the pixel recessed portion.

In the display panel provided by one or more embodiments of the present disclosure, the curvature of the light emitting functional layer of at least one of the first sub-pixel and the second sub-pixel is greater than the curvature of the light emitting functional layer of the third sub-pixel.

In the display panel provided by one or more embodiments of the present disclosure, an area of a light emitting area of the first sub-pixel is less than an area of a light emitting area of the second sub-pixel, and the area of the light emitting area of the second sub-pixel is less than an area of a light emitting area of the third sub-pixel; and
the curvature of the light emitting functional layer of the first sub-pixel is greater than the curvature of the light emitting functional layer of the second sub-pixel, and the curvature of the light emitting functional layer of the second sub-pixel is greater than the curvature of the light emitting functional layer of the third sub-pixel.

In the display panel provided by one or more embodiments of the present disclosure, the sub-pixel includes a second electrode, an encapsulation layer and one or more color film patterns, wherein the second electrode covers the light emitting functional layer, the encapsulation layer covers the second electrode, and the color film patterns are located on a side of the encapsulation layer away from the second electrode; and
a fourth cambered surface is arranged at a part of the encapsulation layer overlapping with the orthographic projection of the first cambered surface on the driving substrate, wherein a curvature of the fourth cambered surface is less than the curvature of the first cambered surface.

In the display panel provided by one or more embodiments of the present disclosure, the color film patterns include a lens structure, wherein the lens structure covers the fourth cambered surface, and an orthographic projection of the color film patterns on the driving substrate covers the orthographic projection of the first cambered surface on the driving substrate.

In the display panel provided by one or more embodiments of the present disclosure, one or more light shielding patterns are arranged between the color film patterns of adjacent two sub-pixels, and a partial region of the color film patterns is arranged on a side of the light shielding patterns away from the driving substrate; and
the region surrounded by the orthographic projection of the outer contour of the second groove on the driving substrate falls within an orthographic projection of the light shielding patterns on the driving substrate.

In the display panel provided by one or more embodiments of the present disclosure, there is an overlap area between the color film patterns of adjacent two sub-pixels, and the region surrounded by the orthographic projection of the outer contour of the second groove on the driving substrate falls within an orthographic projection of the overlap area on the driving substrate.

In the display panel provided by one or more embodiments of the present disclosure, a size of the overlap area is greater than or equal to the size of the second groove in the same direction parallel to the plane where the driving substrate is located.

In the display panel provided by one or more embodiments of the present disclosure, a height of the color film patterns in the direction perpendicular to the plane where the driving substrate is located is greater than a width of the color film patterns in the direction parallel to the plane where the driving substrate is located.

In the display panel provided by one or more embodiments of the present disclosure, a height of the overlap area between the color film patterns of adjacent two sub-pixels in the direction perpendicular to the plane where the driving substrate is located is greater than a width of the color film patterns in the direction parallel to the plane where the driving substrate is located.

In a second aspect, the embodiments of the present disclosure provide a display device including the display panel according to any one of the first aspect.

The above description is only an overview of the technical solutions of the present disclosure. In order to understand technical means of the present disclosure more clearly, it can be implemented according to contents of the specification, and in order to make the above and other purposes, features and advantages of the present disclosure more obvious and understandable, the specific embodiments of the present disclosure are provided below.

### BRIEF DESCRIPTION OF THE DRAWINGS

In order to more clearly explain the technical solutions in the embodiments of the present disclosure or the related art, drawings needed in the description of the embodiments or the related art will be briefly introduced below. Obviously, the drawings described below are only some embodiments of the present disclosure. For a person skilled in the art, other drawings can be obtained according to these drawings without creative work.

FIG. 1 is an explanatory diagram of a method for manufacturing a display panel provided by an embodiment of the present disclosure.

FIG. 2 to FIG. 6 are schematic partial structural, diagrams of five display panels provided by embodiments of the present disclosure.

FIG. 7 is an enlarged partial structural diagram of a pixel opening in FIG. 4.

FIG. 8 and FIG. 9 are schematic positional arrangement diagrams of two columnar connection electrodes provided by embodiments of the present disclosure.

FIG. 10 and FIG. 11 are schematic partial structural diagrams of two display panels provided by embodiments of the present disclosure.

FIG. 12 and FIG. 13 are schematic positional arrangement diagrams of two columnar connection electrodes provided by embodiments of the present disclosure.

FIG. 14 and FIG. 15 are schematic structural diagrams of two driving substrates provided by embodiments of the present disclosure.

FIG. 16A to FIG. 19 are schematic partial structural diagrams of five display panels provided by embodiments of the present disclosure.

FIG. 20 is a schematic partial enlarged diagram of an overlap area in FIG. 19.

FIG. 21 to FIG. 23 are schematic partial structural diagrams of three display panels provided by embodiments of the present disclosure.

FIG. 24 is a schematic simplified structural diagram of a display panel with a single-layer light emitting sublayer provided by an embodiment of the present disclosure.

FIG. 25 and FIG. 26 are schematic simplified structural diagrams of two display panels with double-layer light emitting sublayers provided by embodiments of the present disclosure.

FIG. 27 is a schematic structural diagram of a display device provided by an embodiment of the present disclosure.

FIG. 28 is a schematic structural diagram of a pixel driving circuit provided by an embodiment of the present disclosure.

FIG. 29 is a timing diagram of the pixel driving circuit in FIG. 28.

FIG. 30 to FIG. 33 are schematic top view structural diagrams of four sub-pixels provided by embodiments of the present disclosure.

### DETAILED DESCRIPTION

Technical solutions in embodiments of the present disclosure will be clearly and completely described below with reference to the drawings in the embodiments of the present disclosure. Obviously, the described embodiments are only a part of the embodiments of the present disclosure, but not the whole embodiments. Based on the embodiments of the present disclosure, all other embodiments obtained by a person skilled in the art without creative work belong to the protection scope of the present disclosure.

In the embodiments of the present disclosure, words “first”, “second”, “third” and “fourth” are used to distinguish the same or similar items with basically the same functions and effects, only to clearly describe the technical solutions of the embodiments of the present disclosure, and cannot be understood as indicating or implying relative importance or implicitly indicating the number of indicated technical features.

In the embodiments of the present disclosure, terins “up” and “down” indicate the orientation or positional relationship based on the orientation or positional relationship shown in the accompanying drawings, only for the convenience of describing the present disclosure and simplifying the description, and do not indicate or imply that the devices or elements referred to must have a specific orientation, be constructed and operated in a specific orientation, and therefore cannot be understood as limitations on the present disclosure.

In the description of the specification, terms “one embodiment”, “some embodiments”, “exemplary embodiments”, “an example”, “specific examples” or “some examples” are intended to indicate that specific features, structures, materials or characteristics related to the embodiments or examples are included in at least one embodiment or example of the present disclosure. The schematic representations of the above terms do not necessarily refer to the same embodiment or example. In addition, the described specific features, structures, materials or characteristics may be included in any one or more embodiments or examples in any appropriate manner.

In the embodiments of the present disclosure, “a plurality of” means two or more, and “at least one” means one or more, unless otherwise specifically defined.

The features “parallel”, “perpendicular” and “same” used in the embodiments of the present disclosure all include features such as “parallel”, “perpendicular” and “same” in the strict sense, and the conditions such as “approximately parallel”, “approximately perpendicular”, “approximately the same” contain certain tolerances. Considering the measurement and the tolerance related to the measurement of a specific quantity (for example, limitations of measurement systems), the expression is within the acceptable deviation range for a specific value determined by a person skilled in the art. For example, “approximately” can mean within one or more standard deviations, or within 10% or 5% of the stated value.

Unless the context requires otherwise, throughout the specification and claims, the term “including” is interpreted as an open and inclusive meaning, that is, “including but not limited to”.

“Same layer” in the embodiments of the present disclosure refers to the relationship between a plurality of film layers formed of the same material after the same step (for example, one-step patterning process). The “same layer” herein does not always mean that the thickness of the plurality of film layers is the same or the height of the plurality of film layers in cross-sectional view is the same. Polygons in this specification are not strictly defined, but can be approximate triangles, parallelograms, trapezoids, pentagon or hexagons, and the like, and there can be some small deformations caused by tolerances.

Existing silicon-based organic light emitting diode (OLED) display panels cannot meet requirements of augmented reality (AR) and virtual reality (VR) for high brightness and high pixels per inch (PPI). At present, there are two main solutions. One solution is to arrange a microlens array structure on a light emitting side of light emitting functional layers of sub-pixels. However, the process of making microlenses is complicated, the stability is poor, and materials of the microlenses need to be heated to about 100° C. during the thermal reflux process. High temperatures have adverse effects on light emitting materials, thereby leading to the failure of OLED devices. Another solution is to arrange the microlens array structure on a cover plate of a display panel, and then assemble a light emitting substrate and the cover plate together through the alignment process to form the display panel. However, for OLED display panels with high PPI, the precision of the alignment process is difficult to achieve the precise alignment of the sub-pixels, which is prone to inaccurate alignment, and greatly reduces the yield of the manufacturing process.

Based on this, the embodiments of the present disclosure provide a display panel and a display device. The display panel includes a driving substrate and a plurality of sub-pixels arranged in an array on the driving substrate, wherein each of the plurality of sub-pixels includes a pixel definition layer, a first electrode and one or more light emitting functional layers. The pixel definition layer includes a pixel opening, wherein the pixel opening includes one or more first grooves; the first electrode is arranged between the pixel definition layer and the driving substrate, wherein a partial region of the first electrode serves as a bottom of the pixel opening; and the light emitting functional layers are at least arranged in the first grooves, wherein a part of a surface of the light emitting functional layers on a side away from the driving substrate located in the first grooves includes a first cambered surface, wherein the first groove includes a middle region and an edge region surrounding the middle region, and in the first groove, a distance between a part of the first cambered surface located in the middle region and the driving substrate is greater than a distance between a part of the first cambered surface located in the edge region and the driving substrate in a direction perpendicular to a plane where the driving substrate is located.

In this way, by arranging the pixel opening to include one or more first grooves, the light emitting functional layers are at least arranged in the first grooves, the part of the surface of the light emitting functional layers on the side away from the driving substrate located in the first grooves includes the first cambered surface, and in the first groove, the distance between the part of the first cambered surface located in the middle region and the driving substrate is greater than the distance between the part of the first cambered surface located in the edge region and the driving substrate in the direction perpendicular to the plane where the driving substrate is located, a light emitting surface of the light emitting functional layer in the first groove in the pixel opening can form a structure similar to a convex lens, and there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display panel to a great extent, and further improving the display effect.

Hereinafter, a display panel and a display device provided by the embodiments of the present disclosure will be specifically introduced and explained in conjunction with the accompanying drawings.

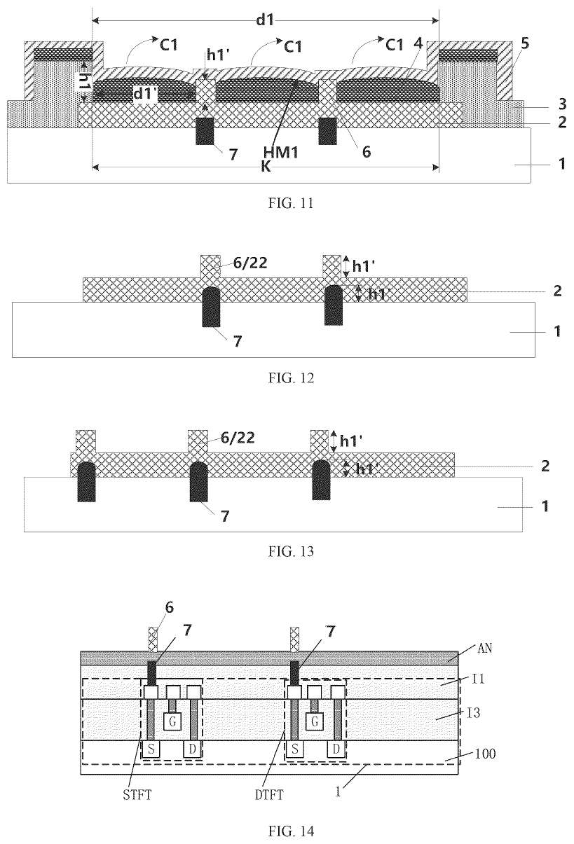

The embodiments of the present disclosure provide a display panel, as shown in FIG. 2 to FIG. 6, FIG. 10 and FIG. 11, FIG. 16A to FIG. 19 and FIG. 21 to FIG. 23. The display panel includes a driving substrate 1 and a plurality of sub-pixels arranged in an array on the driving substrate 1, wherein each of the plurality of sub-pixels includes:
a pixel definition layer 3 including a pixel opening K, wherein the pixel opening K includes one or more first grooves C1;
a first electrode 2 arranged between the pixel definition layer 3 and the driving substrate 1, wherein a partial region of the first electrode 2 serves as a bottom of the pixel opening K; and
one or more light emitting functional layers 4 at least arranged in the first grooves C1, wherein a part of a surface of the light emitting functional layers 4 on a side away from the driving substrate 1 located in the first grooves C1 includes a first cambered surface HM1,
wherein the first groove C1 includes a middle region and an edge region surrounding the middle region, and in each first groove C1, as indicated by markings in FIG. 2, a distance J1 between a part of the first cambered surface HM1 located in the middle region and the driving substrate 1 is greater than a distance J2 between a part of the first cambered surface HM1 located in the edge region and the driving substrate 1 in a direction perpendicular to a plane where the driving substrate 1 is located.

In some exemplary embodiments, the above display panel can be an organic light emitting diode (OLED) display panel.

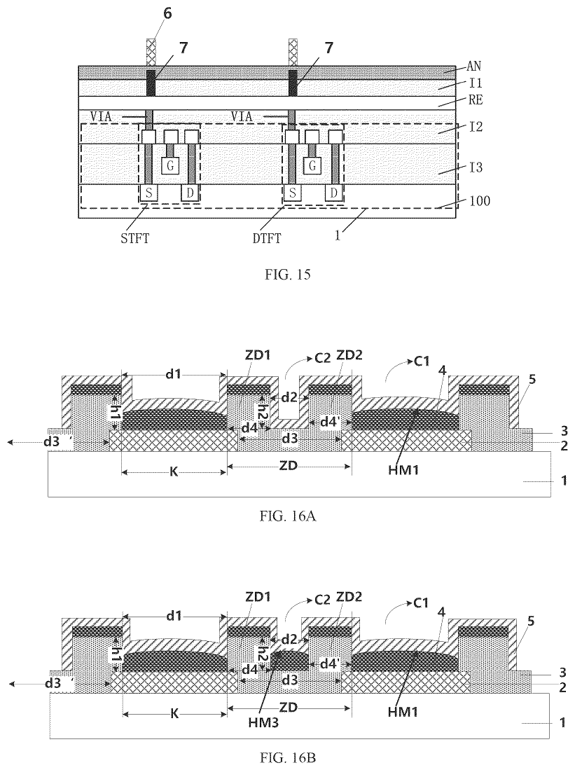

In some exemplary embodiments, the above driving substrate 1 includes a substrate 100 and a driving unit as shown in FIG. 14 or FIG. 15.

In some examples, the material of the substrate 100 can be made of one or more materials of glass, polyimide, polycarbonate, polyacrylate, polyetherimide and polyethersulfone, and the embodiments of the present disclosure include but are not limited to these.

In some examples, the substrate 100 can be a rigid substrate or a flexible substrate.

When the substrate is the rigid substrate, the substrate can include a glass substrate or a silicon material substrate.

For example, the substrate 100 can be a Si substrate.

Specifically, the Si substrate can be a P-type monocrystalline silicon substrate or an N-type monocrystalline silicon substrate, which can be determined according to actual products. At this time, the display panel is a silicon-based OLED display product, which is widely used in fields of near-eye display, virtual reality (VR) and augmented reality (AR), especially in AR/VR head-mounted display devices.

In some exemplary embodiments, the driving unit can include two transistors and one capacitor (2T1C). Alternatively, the driving unit can include four transistors and one capacitor (4T1C). Alternatively, the driving unit can include five transistors and one capacitor (5T1C). In the present disclosure, embodiments of the driving unit 1 are not limited to these. In other embodiments, the driving unit can also include more transistors, more capacitors; or other devices.

In addition, types of transistors in the above driving unit are not limited here: For example, the transistors can include N-type transistors. Alternatively, the transistors can include P-type transistors. Alternatively, the transistors can include both N-type transistors and P-type transistors.

In the embodiments of the present disclosure, the driving unit can be understood as a pixel driving circuit.

Herein, an arrangement manner of the above plurality of sub-pixels is not limited. The arrangement manner can be any arrangement manner in the related art, which can be referred to the introduction in the related art for details.

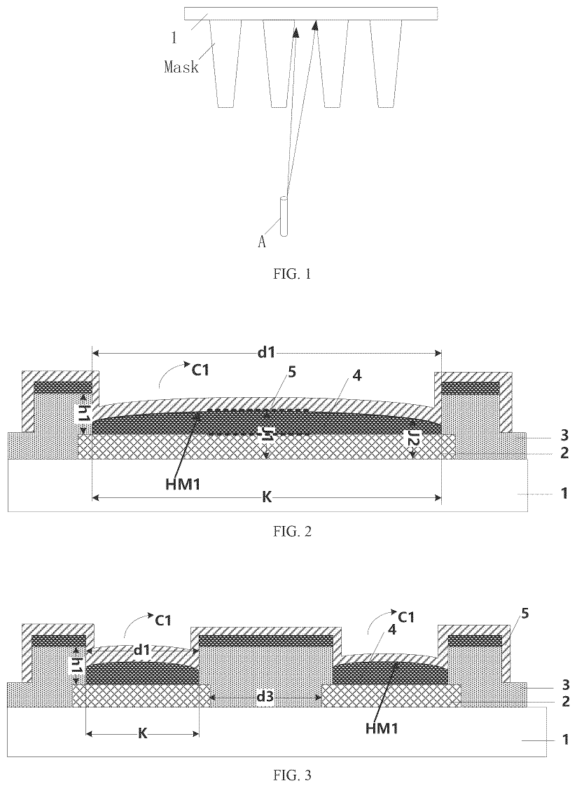

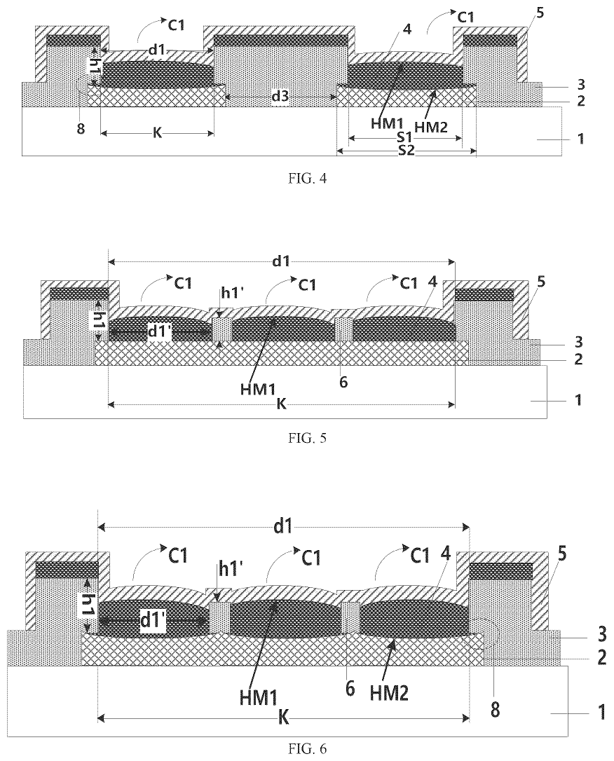

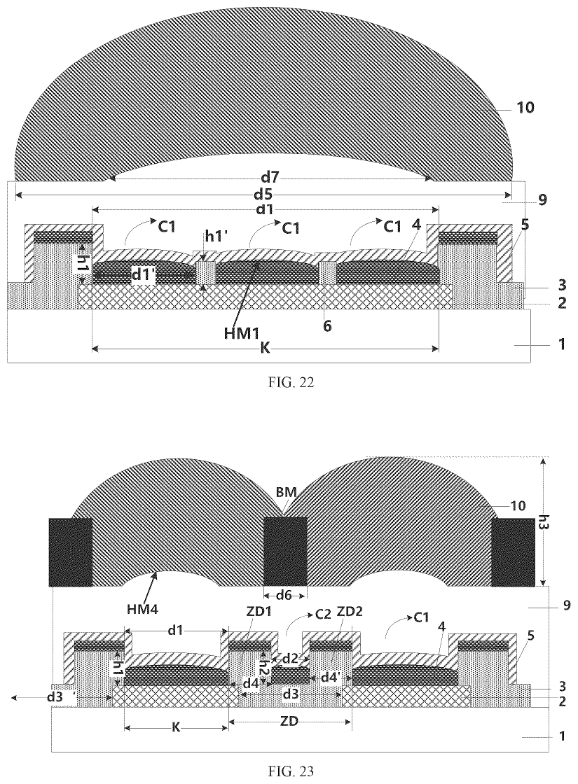

It should be noted that FIG. 2, FIG. 5, FIG. 6, FIG. 10, FIG. 11 and FIG. 22 all show schematic structural diagrams including one sub-pixel; and FIG. 3, FIG. 4, FIG. 16A to FIG. 19, FIG. 21 and FIG. 23 all show schematic structural diagrams including two sub-pixels.

Herein, display colors of the plurality of sub-pixels are not limited.

In some embodiments, the display colors of respective sub-pixels in the above display panel are the same. In some embodiments, the above display panel simultaneously includes a plurality of sub-pixels with different display colors, for example, red sub-pixels, green sub-pixels and blue sub-pixels.

In some exemplary embodiments, each of the sub-pixels includes a light emitting device. The light emitting device includes a light emitting functional layer 4 and a first electrode 2 and a second electrode 5 located at both sides of the light emitting functional layer 4. The first electrode 2 is located between the light emitting functional layer 4 and the driving substrate 1, and at least a part of the second electrode 5 is located on a side of the light emitting functional layer 4 away from the driving substrate 1.

In some exemplary embodiments, the light emitting functional layer 4 includes a plurality of light emitting functional sublayers. It should be noted that the above light emitting functional layer 4 includes not only film layers that directly emit light, but also functional film layers for assisting light emission, for example, hole transporting layers, electron transporting layers, and the like.

Herein, light emitting colors of the plurality of light emitting devices are not limited.

In some exemplary embodiments, the light emitting colors of all light emitting devices are the same. For example, all light emitting devices emit blue light; for another example, all light emitting devices emit white light. At this time, when used for display, it is necessary to arrange a color conversion layer on a light emitting side of the light emitting device. For example, color filters can be arranged on the light emitting side of the light emitting device, for example, red filters, green filters and blue filters. For another example, quantum dot layers with different colors can be arranged on the light emitting side of the light emitting device, for example, red 1 quantum dot layers, green quantum dot layers and white resin layers. The blue light emitted by the light emitting functional layer passes through the red quantum dot layer and emits the red light, the blue light emitted by the light emitting functional layer passes through the green quantum dot layer and emits the green light, and the blue light emitted by the light emitting functional layer passes through the white resin layer and emits the blue light, thereby realizing color display.

In some exemplary embodiments, the above display panel simultaneously includes a plurality of light emitting devices with different light emitting colors, for example, red light emitting devices, green light emitting devices and blue light emitting devices.

It should be noted that the light emitting colors of the light emitting devices can be determined by arranging the material of the light emitting functional layer 4.

FIG. 25 and FIG. 26 show schematic structural diagrams of the light emitting functional layer 4 including two light emitting sublayers in the display panel.

For example, as shown in FIG. 25 and FIG. 26, the light emitting color of the light emitting devices in the display panel is white.

For example, as shown in FIG. 26, the material of guest sublayers 1K in a light emitting sublayer 1B includes blue fluorescent materials, materials of some of the guest sublayers 1K in a light emitting sublayer 1YG include green phosphorescent materials and yellow phosphorescent materials.

For example, as shown in FIG. 25, the material of the guest sublayers 1K in the light emitting sublayer 1B includes blue fluorescent materials, materials of some of the guest sublayers 1K in a light emitting sublayer 1RG include green phosphorescent materials and red phosphorescent materials.

The above display panel further includes a driving substrate 1 (BP) and color filters CFs, for example, the color filters include a red filter pattern CF-R, a green filter pattern CF-G and a blue filter pattern CF-B. Of course, the above display panel can also include other structures and components, which can be referred to the introduction in the related art for details, and will not be repeated here.

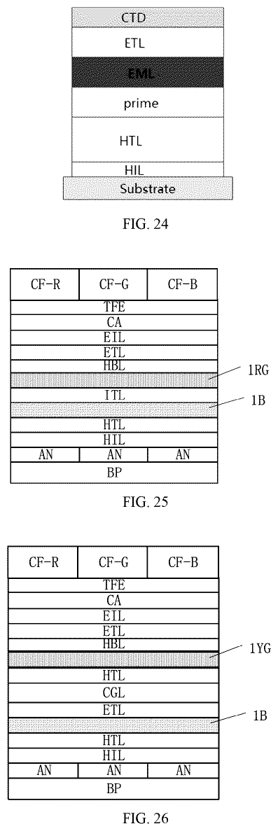

In addition, FIG. 24 shows a schematic structural diagram of the light emitting functional layer 4 including one light emitting sublayer in the display panel.

In some examples, the first electrode 2 can use any one or more of metal materials such as magnesium (Mg), silver (Ag), copper (Cu), aluminum (Al), titanium (Ti) and molybdenum (Mo), or alloy materials of the above metals, for example, aluminum neodymium alloy (AlNd) or molybdenum niobium alloy (MoNb).

In some examples, the second electrode 5 can use any one or more of metal materials such as magnesium (Mg), silver (Ag) and aluminum (Al), or alloys made of any one or more of the above metals, or transparent conductive materials.

For example, the first electrode 2 can be an anode (CA), the second electrode 5 can be a cathode (CTD), and a plurality of sub-pixels can share the second electrode 5. For example, the cathode can be made of materials with high conductivity and low work function, for example, the cathode can be made of metal materials. For example, the anode can be made of transparent conductive materials with high work function.

In some exemplary embodiments, the above pixel definition layer 3 is used to space the light emitting functional layers 4 in adjacent two sub-pixels, wherein the pixel opening K in the pixel definition layer 3 is also called a pixel opening area, and the pixel opening area is a region that actually emits light in the sub-pixel.

It should be noted that since a partial region of the first electrode 2 serves as a bottom of the pixel opening K, it is not limited whether the bottom of the pixel opening K is a plane or a cambered surface. For example, the bottom of the pixel opening K (that is, a partial region of a surface of the first electrode 2 on a side away from the driving substrate 1) is the plane.

In some exemplary embodiments, a thickness of the pixel definition layer 3 is greater than a thickness of the light emitting functional layer 4.

In some exemplary embodiments, the pixel definition layer 3 can include a sublayer.

For example, the material of the pixel definition layer 3 can include organic materials such as polyimide, acrylic or polyethylene terephthalate.

In some exemplary embodiments, the pixel definition layer 3 can include a plurality of sublayers. For example, the pixel definition layer 3 can include a first sublayer, a second sublayer and a third sublayer.

For example, the material of the pixel definition layer 3 can include inorganic materials such as at least one of silicon oxide; silicon nitride and silicon oxynitride.

For example, the material of the first sublayer of the pixel definition layer 3 is silicon oxide, the material of the second sublayer of the pixel definition layer 3 is silicon nitride, and the material of the third sublayer of the pixel definition layer 3 is silicon oxide.

In some embodiments, as shown in FIG. 2 to FIG. 4, one pixel opening K includes one first groove C1. In other embodiments, as shown in FIG. 5 and FIG. 6, one pixel opening K includes a plurality of first grooves C1, wherein the plurality of first grooves C1 include two or more first grooves C1.

In the case where sizes of the pixel openings K are related, the more the number of the first grooves C1 in the same pixel opening K, the greater the curvature of the first cambered surface HM1 formed by the light emitting functional layer 4 in the first grooves C1.

Hereinafter, a reason why the first cambered surface HM1 can be formed at the part of the surface of the light emitting functional layer 4 on the side away from the driving substrate 1 located in the first groove C1 will be explained in conjunction with FIG. 1. In the process of actually manufacturing the display panel, an evaporation source A forms the light emitting functional layer 4 on the driving substrate 1 through a mask plate Mask. However, since the evaporation source A and an opening position on the mask plate Mask are not opposite, it is easy to generate a shadow effect, that is, the light emitting functional layer 4 is thick in the middle and thin on both sides. In OLED light emitting devices with relatively large pixel sizes; this effect is generally not obvious. However, in silicon-based microdisplay panels, since the size of the sub-pixels is extremely small (5 μm~10 μm), an evaporation shadow effect will be more obvious. At this time, by using one or more first grooves C1 arranged in the pixel opening K, the number of the first grooves C1 in the same pixel opening K can be determined according to size effects, and thus the first cambered surface HM1 can be formed at the surface of the light emitting functional layer 4 on the side away from the driving substrate 1 located in the first grooves C1 of the pixel opening K.

Herein, a specific boundary between the middle region and the edge region in the first groove C1 is not limited, and the specific boundary can be actually determined according to the size of the first groove C1.

In the display panel provided by the embodiments of the present disclosure, since in each first groove C1, as indicated by markings in FIG. 2, the distance J1 between the part of the first cambered surface HM1 located in the middle region and the driving substrate 1 is greater than the distance J2 between the part of the first cambered surface HM1 located in the edge region and the driving substrate 1 in the direction perpendicular to the plane where the driving substrate 1 is located, each first cambered surface HM1 in the first groove C1 can form a structure similar to a convex lens, and thus the light emitted by the light emitting functional layer 4 is converged within the range of the first groove C1, and there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display panel to a great extent, and further improving the display effect.

In some exemplary embodiments, the light emitting functional layer 4 (EL) includes one or more light emitting sublayers (EML). For example, the light emitting functional layer 4 includes one light emitting sublayer (EML); alternatively, the light emitting functional layer 4 includes two light emitting sublayers (EML).

When the light emitting functional layer 4 includes two or more light emitting sublayers, the light emitting functional layer 4 further includes a plurality of functional sublayers in a direction perpendicular to the driving substrate 1.

For example, the plurality of functional sublayers include a hole injection layer, a hole transporting layer, a first light emitting sublayer, an electron transporting layer, a charge generation layer, a hole transporting layer, a second light emitting sublayer, an electron transporting layer, a charge generation layer, a hole transporting layer, a third light emitting sublayer, an electron transporting layer and an electron injection layer, which are sequentially arranged on the anode.

For another example, the plurality of functional sublayers include a hole injection layer, a hole transporting layer, a first light emitting sublayer, an electron transporting layer, a charge generation layer, a hole transporting layer, a second light emitting sublayer, an electron transporting layer and an electron injection layer. Of course, as shown in FIG. 25 or FIG. 26, a hole blocking layer HBL can also be arranged between the second light emitting sublayer and the electron transporting layer; alternatively, an electron blocking layer can be arranged between the first light emitting sublayer and the hole transporting layer.

The above structure includes two or more light emitting sublayers is called Tandem EL design, and the specific structure can be referred to the introduction in the related art, which will not be described here.

In addition, film layers such as the hole transporting layer (HTL), the electron blocking layer (EBL), the hole injection layer (HIL), the electron transporting layer (ETL) and the electron injection layer. (EIL) can be collectively referred to as common layers. The common layers of all sub-pixels in the display panel can be shared, that is, the common layers of any adjacent two sub-pixels are connected into a whole.

In the display panel provided by one or more embodiments of the present disclosure, as shown in FIG. 2 to FIG. 6, FIG. 10 and FIG. H, FIG. 16A to FIG. 19 and FIG. 21 to FIG. 23, a ratio between a depth h1 of the pixel opening K in the direction perpendicular to the plane where the driving substrate 1 is located and a maximum size d1 of the pixel opening K in a direction parallel to the plane where the driving substrate 1 is located is greater than or equal to 0.3.

For example, the ratio between the depth h1 of the pixel opening K in the direction perpendicular to the plane where the driving substrate 1 is located and the maximum size d1 of the pixel opening K in the direction parallel to the plane where the driving substrate 1 is located is greater than or equal to 0.4.

In the process of actually manufacturing the display panel, according to the shadow effect described above; when the depth h1 and the width d1 of the pixel opening K satisfy h1/d1≥0.3, it can be ensured that the surface of the light emitting functional layer 4 formed (evaporated or deposited) in the pixel opening K on the side away from the driving substrate 1 has the first cambered surface HM1, and the distance J1 between the part of the first cambered surface HM1 located in the middle region and the driving substrate 1 is greater than the distance J2 between the part of the first cambered surface HM1 located in the edge region and the driving substrate 1. In this way, it can be ensured that a convex lens or a structure similar to a convex lens can be formed, thereby converging the light.

However, in the subsequent manufacturing process, inventors found that when the depth h1 and the width d1 of the pixel opening K satisfy h1/d1>0.8, it is difficult for the second electrode 5 to form a continuous structure, and local fracture may be easily generated. Therefore, in order to improve the yield of manufacturing the display panel provided by the embodiment's of the present disclosure, in the display panel provided by one or more embodiments of the present disclosure, as shown in FIG. 2 to FIG. 6, FIG. 10 and FIG. 11, FIG. 16A to FIG. 19 and FIG. 21 to FIG. 23, the ratio between the depth h1 of the pixel opening K in the direction perpendicular to the plane where the driving substrate 1 is located and the maximum size d1 of the pixel opening K in the direction parallel to the plane where the driving substrate 1 is located is set to be greater than or equal to 0.3 and less than or equal to 0.8, that is, 0.8≥h1/d1≥0.3.

For example, according to requirements of the curvature of the first cambered surface HM1, 0.7≥h1/d1≥0.3, 0.7≥h1/d1≥0.4, 0.65≥h1/d1≥0.3, 0.5≥h1/d1≥0.3, 0.65≥h1/d1≥0.4 or 0.65≥h1/d1≥0.5 can be set.

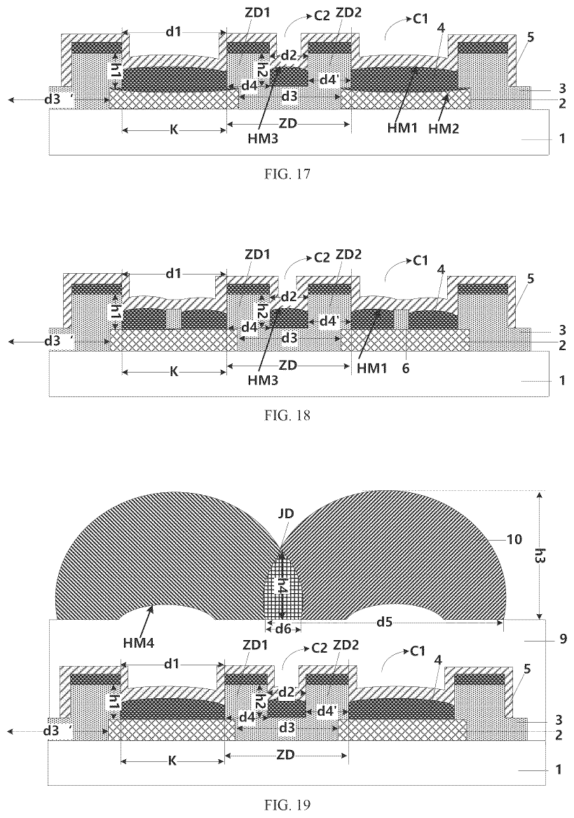

In the display panel provided by one or more embodiments of the present disclosure, as shown in FIG. 2, FIG. 3, FIG. 4, FIG. 16A, FIG. 16B, FIG. 17, FIG. 19, FIG. 21 and FIG. 23, the pixel opening K includes one of the first grooves C1, and a maximum size of the sub-pixel in the direction parallel to the plane where the driving substrate 1 is located is less than or equal to 2 μm.

In some exemplary embodiments, when the maximum size of the sub-pixel in the direction parallel to the plane where the driving substrate 1 is located is less than or equal to 2 μm, in the process of actually manufacturing the display panel, the shadow effect can occur in the pixel opening K of almost every sub-pixel, so that the light emitting functional layer 4 formed in the pixel opening K is thick in the middle and thin on both sides, that is, the first cambered surface HM1 mentioned above can be formed. Therefore, it is not necessary to arrange a plurality of first grooves C1 in the same pixel opening K to aggravate the size effect, and it is possible to ensure that a structure similar to a convex lens can be formed in each sub-pixel to converge the light emitted by the light emitting functional layer 4.

In this way, there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display panel to a great extent, and further improving the display effect.

In the display panel provided by one or more embodiments of the present disclosure, as shown in FIG. 5, FIG. 6, FIG. 10, FIG. 11, FIG. 18 and FIG. 22, the pixel opening K includes two or more of the first grooves C1, and a maximum size of the sub-pixel in the direction parallel to the plane where the driving substrate 1 is located is less than or equal to 2 μm.

In some exemplary embodiments, when the maximum size of the sub-pixel in the direction parallel to the plane where the driving substrate 1 is located is less than or equal to 2 μm, in the process of actually manufacturing the display panel, it is impossible to ensure that the shadow effect occurs in each pixel opening K, and it is impossible to ensure that the light emitting functional layer 4 formed in each pixel opening K is thick in the middle and thin on both sides: Therefore, in order to aggravate the shadow effect, the pixel opening K is arranged to include two or more first grooves C1, and a maximum size of the first grooves C1 in the direction parallel to the plane where the driving substrate 1 is located is less than the maximum size of the sub-pixel in the direction parallel to the plane where the driving substrate 1 is located, so that the shadow effect can be aggravated to a great extent.

Herein, the specific number of the first grooves C1 included in the same pixel opening K is not limited. In practical applications, the larger the size of the sub-pixel, the more the number of the first grooves C1 included in the same pixel opening K, thereby ensuring the effect of the shadow effect, and ensuring that the first cambered surface HM1 with a structure similar to a convex lens can be formed in each first groove C1.

In the display panel provided by one or more embodiments of the present disclosure, as shown in FIG. 5, FIG. 6, FIG. 10, FIG. 11, FIG. 18 and FIG. 22, the pixel opening K further includes one or more spacers 6 located between adjacent two of the first grooves C1, and a ratio between a depth h1′ of the first groove C1 in the direction perpendicular to the plane where the driving substrate 1 is located and a maximum size d1′ of the first groove C1 in the direction parallel to the plane where the driving substrate 1 is located is greater than or equal to 0.3 and less than or equal to 0.8, that is, 0.8≥h1′/d1′≥0.3.

For example, 0.7≥h1′/d1′≥0.3, 0.7≥h1′/d1′≥0.4, 0.65≥h1′/d1′≥0.3, 0.5≥h1′/d1′≥0.3, 0.65≥h1′/d1′≥0.4 or 0.65≥h1′/d1′≥0.5 can be set.

By arranging the spacers 6 located between adjacent two of the first grooves C1, and the ratio between the depth h1′ of the first groove C1 in the direction perpendicular to the plane where the driving substrate 1 is located and the maximum size d1′ of the first groove C1 in the direction parallel to the plane where the driving substrate 1 is located is greater than or equal to 0.3 and less than or equal to 0.8, it can be ensured that the surface of the light emitting functional layer 4 on the side away from the driving substrate 1 located in the first grooves C1 of the pixel opening K has the first cambered surface HM1, and the distance J1 between the part of the first cambered surface HM1 located in the middle region and the driving substrate 1 is greater than the distance J2 between the part of the first cambered surface HM1 located in the edge region and the driving substrate 1. In this way, it can be ensured that a convex lens or a structure similar to a convex lens can be formed, thereby converging the light.

In the display panel provided by one or more embodiments of the present disclosure, as shown in FIG. 5, FIG. 6, FIG. 10, FIG. 11, FIG. 18 and FIG. 22, the ratio (that is, h1/d1) between the depth h1 of the pixel opening K in the direction perpendicular to the plane where the driving substrate 1 is located and the maximum size d1 of the pixel opening K in the direction parallel to the plane where the driving substrate 1 is located is greater than the ratio (that is, h1′/d1′) between the depth h1′ of the first groove C1 in the direction perpendicular to the plane where the driving substrate 1 is located and a maximum size d1′ of the first groove C1 in the direction parallel to the plane where the driving substrate 1 is located, that is, h1/d1>h1′/d1′.

In the embodiments of the present disclosure, when h1/d1>h1′/d1′, since a depth-width ratio of the pixel opening is relatively large, one or more sublayers in the light emitting functional layer 4 at a local position of the pixel definition layer 3 between the pixel openings K of adjacent two sub-pixels can be disconnected, so that the light emitting functional layer 4 between adjacent two sub-pixels is disconnected at the local position of the pixel definition layer 3 between adjacent two pixel openings, thereby effectively avoiding light crosstalk between adjacent two sub-pixels.

In the display panel provided by one or more embodiments of the present disclosure, as shown in FIG. 5 or FIG. 6, the spacers 6 and the pixel definition layer 3 are arranged in the same layer.

The same layer arrangement means that the spacers 6 and the pixel definition layer 3 are manufactured using the same process in the same step, and raw materials used are the same, and thus materials of finished products are also the same.

In some embodiments, a height of the spacers 6 in a direction perpendicular to the plane where the driving substrate 1 is located is less than or equal to a distance between the first electrode 2 and the surface of the pixel definition layer 3 on the side away from the driving substrate 1 in the direction perpendicular to the plane where the driving substrate 1 is located.

In the display panel provided by one or more embodiments of the present disclosure, as shown in FIG. 10 and FIG. 11, the spacers 6 and the first electrode 2 are an integrated structure.

The integrated structure means that the spacers 6 and the first electrode 2 can be connected as a whole, and materials thereof are the same.

In the display panel provided by one or more embodiments of the present disclosure, as shown in FIG. 10 and FIG. 11, the first electrode 2 includes a plurality of contact portions 21 and a plurality of protrusion portions 22, one of the plurality of protrusion portions 22 is arranged between adjacent two of the plurality of contact portions 21, the plurality of contact portions 21 serve as a plurality of bottoms of the first grooves C1, and the plurality of protrusion portions 22 serve as the spacers 6.

The contact portions 21 refer to portions of the first electrode 2 that directly contact with the light emitting functional layer 4, and the protrusion portions 22 and the spacers 6 have the same structure.

In the display panel provided by one or more embodiments of the present disclosure, as shown in FIG. 11 to FIG. 15, the driving substrate 1 includes a plurality of columnar connection electrodes 7, and one or more of the plurality of columnar connection electrodes 7 are in contact connection with the first electrode 2 in the sub-pixel; and an orthographic projection of the columnar connection electrodes 7 on a substrate of the driving substrate 1 is located within an orthographic projection of the plurality of protrusion portions 22 on the substrate, and an end of the columnar connection electrode 7 away from the substrate protrudes from a surface of the driving substrate 1 near the first electrode 2.

In some exemplary embodiments, the end of the columnar connection electrode 7 away from the substrate can be embedded in the first electrode 2.

In some exemplary embodiments, when the driving substrate 1 is a silicon-based driving substrate, the driving substrate 1 includes the plurality of columnar connection electrodes 7 (also called tungsten holes) as shown in FIG. 11 to FIG. 13, for electrically connecting the pixel driving circuit in the driving substrate 1 and the first electrode 2 together.

FIG. 28 shows a schematic structural diagram of a pixel driving circuit. The pixel driving circuit includes a driving module CC2, a first control module CC5, a second control module CC4, an input module CC1 and a compensation module CC3.

The driving module CC2 is electrically connected to a first node G, a second node S and an anode of a light emitting device CC6 respectively, and is configured to conduct a path between the second node S and the anode under the control of a voltage of the first node G to generate a current in the path for enabling the light emitting device CC6 to emit light. The second node S is coupled to a first power signal line ELVDD. The first control module CC5 is electrically connected to a first control signal line AZ, a second power signal line. VSS and the anode of the light emitting device CC6 respectively, and is configured to transmit a second power signal transmitted by the second power signal line VSS to the anode under the control of a first control signal transmitted by the first control signal line AZ. The second control module CC4 is electrically connected to a first power signal line ELVSS, a second control signal line DS and the driving module CC2 respectively, and is configured to transmit a first power signal transmitted by the first power signal line ELVDD to the driving module CC2 under the control of a second control signal transmitted by the second control signal line DS to generate a current in an auxiliary path for enabling the light emitting device CC6 to emit light. The voltage of the first power signal is greater than the voltage of the second power signal. The input module CC1 is electrically connected to a gate line WS, a data line DL and the first node G respectively, and is configured to write a data signal transmitted by the data line DL into the first node G under the control of a scanning signal transmitted by the gate line WS. The compensation module CC3 is electrically connected to the first node G, the second node S and the first power signal line ELVDD respectively, and is configured to compensate a threshold voltage of the driving module CC2.

Specifically, as shown in FIG. 28, the input module CC1 includes a first transistor T1, the driving module CC2 includes a driving transistor DMOS, the second control module CC4 includes a second transistor T2, and the first control module CC5 includes a third transistor T3. A gate of the first transistor T1 is electrically connected to a gate line WS, a source of the first transistor T1 is electrically connected to a data line DL, and a drain of the first transistor T1 is electrically connected to a gate of the driving transistor DMOS, A gate of the second transistor T2 is electrically connected to the second control signal line DS, a source of the second transistor T2 is electrically connected to the first power signal line ELVDD, and a drain of the second transistor T2 is electrically connected to a source of the driving transistor DMOS. A gate of the third transistor T3 is electrically connected to the first control signal line AZ, a source of the third transistor T3 is electrically connected to a drain of the driving transistor DMOS, and a drain of the third transistor T3 is electrically connected to the second power signal line VSS. The compensation module CC3 includes a first capacitor C1 and a second capacitor C2, wherein a first plate of the first capacitor C1 is electrically connected to the source of the driving transistor. DMOS, and a second plate of the first capacitor C1 is electrically connected to the gate of the driving transistor DMOS; a first plate of the second capacitor C2 is electrically connected to the source of the driving transistor DMOS, and a second plate of the second capacitor C2 is electrically connected to the first power signal line, ELVDD.

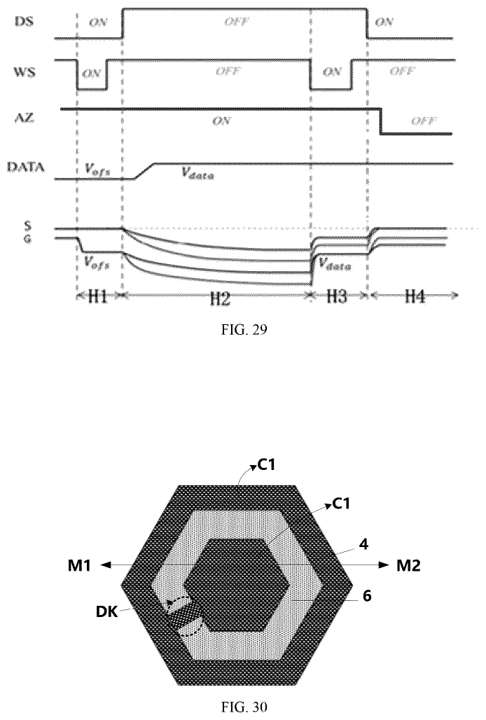

FIG. 29 shows a signal timing diagram of an operation process of the pixel driving circuit shown in FIG. 28, As shown in FIG. 29, the operation process of the pixel driving circuit includes four-stages.

Hereinafter, taking the third transistor T3 as an N-type MOS transistor and the other transistors as P-type MOS transistors in the pixel driving circuit shown in FIG. 28 as an example, the working principle of the pixel driving circuit will be explained in conjunction with the signal timing diagram shown in FIG. 29.
1. In a first stage H1 (Vofs writing stage, also called initialization stage), as shown in FIG. 29, a low-level second control signal is input to the second control signal line DS, a low-level gate drive signal (also called scanning signal) is input to the gate line WS, and a high-level first control signal is input to the first control signal line AZ.

A transistor connected to the second control signal line DS receives the low-level second control signal, a transistor connected to the gate line WS receives the low-level gate drive signal, a transistor connected to the first control signal line AZ receives a low-level first control signal, and the data line DL receives a Vofs voltage signal. The first transistor T1, the second transistor T2 and the third transistor T3 are turned on. The first node G writes a voltage value of Vofs, and the second node S writes a voltage value of Vdd. At this time, Vini=Vdd−Vofs.
2. In a second stage H2 (self-discharge threshold voltage reading stage), as shown in FIG. 29, a high-level second control signal is input to the second control signal line DS, a high-level gate drive signal is input to the gate line WS, and the high-level first control signal is input to the first control signal line AZ.

The transistor connected to the second control signal line DS receives the high-level second control signal, the transistor connected to the gate line WS receives the high-level gate drive signal, and the transistor connected to the first control signal line AZ receives the low-level first control signal. The first transistor T1 and the second transistor T2 are turned off, and the third transistor T3 is turned on. Since the first node G is floating, the voltage of the first node G changes with a voltage of the second node S under the action of the first capacitor C1, so that a voltage difference between the first node G and the second node S remains unchanged in the previous stage, that is, Vgs=Vini=Vdd−Vofs.

Under the action of back gate effect, |V_{TH-EF}|=a*(Vdd−Vs)+|V_{TH}|, where a is a coefficient of the back gate effect, and Vs is the voltage of the second node S. As the voltage Vs of the second node S drops, since Vgs keeps Vini unchanged, when |V_{TH-EF}| increases to Vini, the discharge stops, and the driving transistor DMOS turns off. At this time,

$$a * ( Vdd - Vs ) + \vert {V}_{TH} \vert = Vini = Vdd - Vofs ;$$

$$then , Vs = Vdd + ( \vert {V}_{TH} \vert - Vini ) / a ;$$

$$Vg = Vdd - Vini + ( \vert {V}_{TH} \vert - Vini ) / a .$$

3. In a third stage H3 (Vdata writing and threshold compensation stage), as shown in FIG. 29, the high-level second control signal is input to the second control signal line DS, the low-level gate drive signal is input to the gate line WS, and the high-level first control signal is input to the first control signal line AZ.

The transistor connected to the second control signal line DS receives the high-level second control signal, the transistor connected to the gate line WS receives the low-level gate drive signal, the transistor connected to the first control signal line AZ receives the low-level first control signal. The first transistor T1 and the third transistor T3 are turned on, and the second transistor T2 is turned off. At this time, the first node G writes a Vdata signal, and the voltage of the first node G changes from Vofs to Vdata. Since the second node S is floating, a voltage change value of the second node S is ΔVs,

$$Δ Vs = ( 1 - b ) * Vg , wherein b = C 2 / ( C 1 + C 2 ) ;$$

$$\begin{matrix}Δ Vg = Vdata - Vdd + Vini - ( \vert {V}_{TH} \vert - Vini ) / a \\ = Vdata - Vdd + Vini + ( Vini - \vert {V}_{TH} \vert ) / a\end{matrix} ;$$

$$then , Δ Vs = ( 1 - b ) * [ Vdata - Vdd + Vini + ( Vini - \vert {V}_{TH} \vert ) / a ] ;$$

at this time, the voltage of the second node S is:

$$Vdd - ( Vini - \vert {V}_{TH} \vert ) / a + Δ Vs = Vdd - ( Vini - \vert {V}_{TH} \vert ) / a + ( 1 - b ) * [ Vdata - Vdd + Vini + ( Vini - \vert {V}_{TH} \vert ) / a ] = Vdata + Vini - bVdata + bVdd * b ( Vini - \vert {V}_{TH} \vert ) / a - bVini ;$$

$$then , \vert Vgs \vert = ( 1 - b / a - b ) * Vini + b \vert {V}_{TH} \vert / a + b ( Vdd - Vdata ) .$$

4. In a fourth stage H4 (light emitting stage), as shown in FIG. 29, the low-level second control signal is input to the second control signal line DS, the high-level gate drive signal is input to the gate line WS, and the low-level first control signal is input to the first control signal line AZ.

The transistor connected to the second control signal line DS receives the low-level second control signal, the transistor connected to the gate line WS receives the high-level gate drive signal, and the transistor connected to the first control signal line AZ receives the high-level first control signal. The first transistor T1 and the third transistor T3 are turned off, the second transistor T2 is turned on, and the driving transistor DMOS is turned on.

In a light emitting stage of the light emitting device CC6, a current in a light emitting path between the second node S and the anode is:

$${I}_{oled} = \frac{1}{2} {μ}_{p} {c}_{ox} W / {L [ ( 1 - \frac{b}{a} - b ) {V}_{ini} + b ( {V}_{DD} - {V}_{data} ) + ( \frac{b}{a} - 1 ) \vert {V}_{TH} \vert ]}^{2} = \frac{1}{2} {μ}_{p} {c}_{ox} W / {L [ b ( {V}_{DD} - {V}_{data} ) - {bV}_{ini} ]}^{2} .$$

As can be seen from the above formula, the current in the light emitting path between the second node S and the anode is independent of the threshold voltage V_{TH} of the driving transistor DMOS.

FIG. 14 and FIG. 15 show schematic structural diagrams of two driving substrates. The driving substrate 1 includes a substrate 1 and a pixel driving circuit. The pixel driving circuit at least includes a driving transistor DTFT and a switching transistor STFT (for example, the pixel driving circuit shown in FIG. 28). The driving substrate 1 includes a first insulating layer 11 and a third insulating layer 13, wherein a plurality of columnar connecting electrodes 7 pass through the first insulating layer 11 to electrically connect the pixel driving circuit and an anode AN (the first electrode 2) of the sub-pixel together. In addition, in FIG. 15, the driving substrate 1 further includes a reflective layer RE and a second insulating layer 12, wherein the plurality of columnar connection electrodes 7 are electrically connected to the pixel driving circuit through the reflective layer RE.

In some exemplary embodiments, the reflective layer RE has conductivity.

In some exemplary embodiments, the reflective layer RE includes an aluminum metal layer and a protective layer, wherein the protective layer is located between the aluminum metal layer and the substrate 100. Both the aluminum metal layer and the protective layer have electrical conductivity, and the aluminum metal layer has a good light reflecting effect, so that the light emitted by the light emitting functional layer in a direction of the reflective layer RE can be reflected, thereby improving the luminous efficiency of the display panel, improving the use efficiency of the light emitted by the light emitting functional layer 4, improving the display effect, and reducing the power consumption.

When using the protrusion portions 22 as the spacers 6, the columnar connection electrodes 7 can be arranged at positions below the protrusion portions 22, and an end of the columnar connection electrodes 7 away from the substrate is embedded in the first electrode 2 (that is, the columnar connection electrodes 7 are designed to protrude from the driving substrate 1). In this way, when forming the first electrode 2, under the support of the columnar connection electrodes 7 below, the protrusion portions 22 can be formed, so that the protrusion portions 22 can be used as the spacers 6 to form two or more first grooves C1 in the same pixel opening K.

In some embodiments, in the pixel opening K of the same sub-pixel, a spacer 6 can be provided; at this time, a columnar connection electrode 7 is provided in a region of the driving substrate 1 corresponding to the sub-pixel. In some embodiments, as shown in FIG. 12, in the pixel opening K of the same sub-pixel, two spacers 6 can be provided; at this time, two columnar connection electrodes 7 are provided in the region of the driving substrate 1 corresponding to the sub-pixel. In some embodiments, as shown in FIG. 13, in the pixel opening K of the same sub-pixel, three spacers 6 can be provided; at this time, three columnar connection electrodes 7 are provided in the region of the driving substrate 1 corresponding to the sub-pixel.

In some embodiments, as shown in FIG. 12 and FIG. 13, a size D1 of a part of the columnar connection electrodes 7 embedded in the first electrode 2 in a direction perpendicular to a plane where the substrate is located is approximately equal to a size h1′ of the protrusion portions 22 in the direction perpendicular to the plane where the substrate is located.

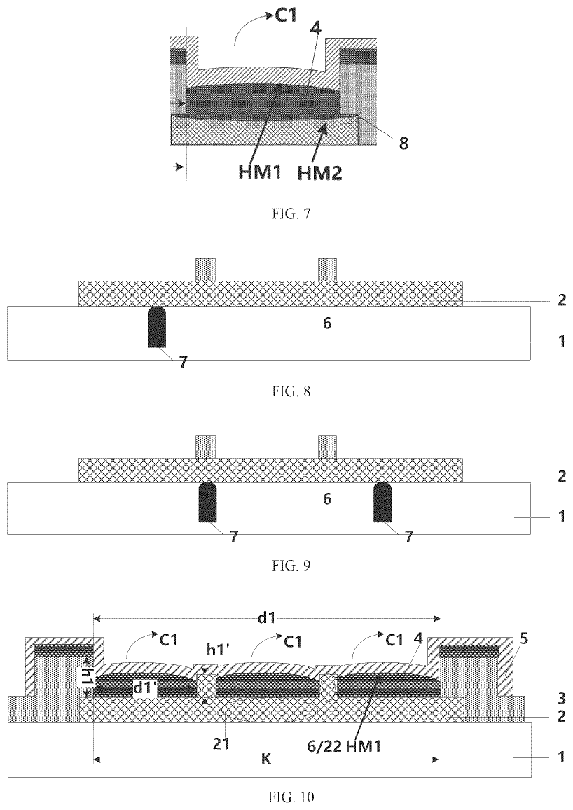

It should be noted that, as shown in FIG. 5 or FIG. 6, when the spacers 6 and the pixel definition layer 3 are arranged in the same layer and the driving substrate 1 is a silicon-based driving substrate, in conjunction with FIG. 8 and FIG. 9, an orthographic projection of the columnar connection electrodes 7 on a substrate of the driving substrate 1 can be arranged within an orthographic projection of the spacers 6 on the substrate; or the orthographic projection of the columnar connection electrode 7 on the substrate of the driving substrate 1 and the orthographic projection of the spacer 6 on the substrate can be arranged not to overlap each other. Of course, at this time, an upper surface of the columnar connection electrode 7 is almost flat with an upper surface of the driving substrate 1, and the columnar connection electrode 7 cannot be embedded in the first electrode 2.

In the display panel provided by one or more embodiments of the present disclosure, as shown in FIG. 30 to FIG. 32, one or more fractures DK are arranged on the spacers 6, and one or more light emitting functional layers 4 in adjacent two first grooves C1 are communicated at positions of the fractures DK. FIG. 5 is a schematic cross-sectional structural diagram of FIG. 30 along a direction of M1M2.

In the display panel provided by one or more embodiments of the present disclosure, orthographic projection patterns of the spacers 6 on the driving substrate 1 include a ring shape or a grid shape.

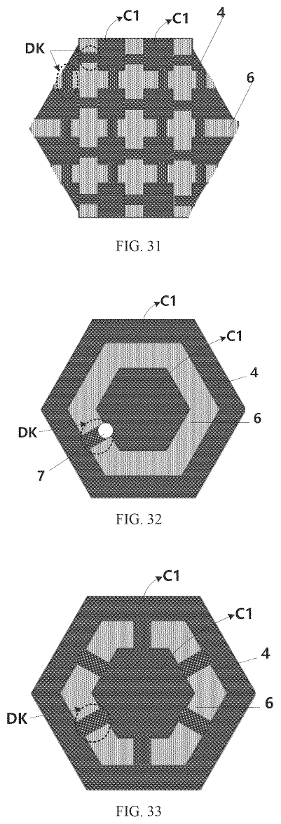

For example, as shown in FIG. 31, the orthographic projection pattern of the spacer 6 on the driving substrate 1 includes the grid shape, where the spacer 6 shown in FIG. 31 is provided with a plurality of fractures DK, and the spacer 6 between any adjacent two first grooves C1 in the same sub-pixel is provided with a fracture DK; so that the light emitting functional layers 4 in all the first grooves C1 in the pixel opening K of the same sub-pixel are connected together.

For example, as shown in FIG. 30 and FIG. 32, the orthographic projection pattern of the spacer 6 on the driving substrate 1 includes the ring shape, and a fracture DK is provided between adjacent two first grooves C1, so that the light emitting functional layers 4 in the two first grooves C1 in the pixel opening K of the same sub-pixel are connected together. Herein, the specific shape of the ring shape is not limited. For example, the ring shape can include an elliptical ring shape, a circular ring shape and a polygonal ring shape (five membered ring shape, six membered ring shape, and the like). For example, an outer contour of the ring shape can be approximately the same as an outer contour of the sub-pixel.

For example, as shown in FIG. 33, the orthographic projection pattern of the spacer 6 on the driving substrate 1 includes a grid-shaped ring shape, and a plurality of fractures DK are arranged between adjacent two first grooves C1, so that the light emitting functional layers 4 in the two first grooves C1 in the pixel opening K of the same sub-pixel are connected together.

By arranging the light emitting functional layers 4 in adjacent two first grooves C1 to communicate at the positions of the fractures DK, when manufacturing the light emitting functional layers 4 of the display panel by using the inkjet printing process, the leveling property of the material of the light emitting functional layers 4 is facilitated, and the thickness uniformity of the light emitting functional layers 4 in the same sub-pixel is improved. In addition, when manufacturing the light emitting functional layers 4 of the display panel by using the inkjet printing process or the evaporation process, it is beneficial to the uniform distribution of the electrical properties of the light emitting functional layers 4 in the same sub-pixel, thereby improving the brightness uniformity and the luminous efficiency.

In the display panel provided by one or more embodiments of the present disclosure, a depth of the fractures DK in the direction perpendicular to the plane where the driving substrate 1 is located is less than or equal to a height of the spacers 6 in the direction perpendicular to the plane where the driving substrate 1 is located.

For example, the depth of the fracture DK can be less than the height of the spacer 6. At this time, a part of the material of the spacer 6 remains at a bottom position of the fracture DK.

For example, the depth of the fracture DK can be equal to the height of the spacer 6. At this time, the bottom position of the fracture DK is an upper surface of the first electrode 2, for example, the contact portion 21 of the first electrode 2.

In the display panel provided by one or more embodiments of the present disclosure, as shown in FIG. 32, a region surrounded by an orthographic projection of an outer contour of at least one fracture DK on the substrate overlaps with the orthographic projection of the columnar connection electrodes 7 on the substrate.

For example, the orthographic projection of the columnar connection electrodes 7 on the substrate overlaps with the regions surrounded by the orthographic projections of the outer contours of different fractures DK on the substrate, respectively.

For example, when an area of the orthographic projection of the columnar connection electrode. 7 on the substrate is less than an area of the region surrounded by the orthographic projection of the outer contour of the fracture DK on the substrate, the orthographic projection of the columnar connection electrode 7 on the substrate can be set in a central region of the region surrounded by the orthographic projection of the outer contour of the fracture DK on the substrate.

In the embodiments of the present disclosure, by arranging the region surrounded by the orthographic projection of the outer contour of at least one fracture DK on the substrate to overlap with the orthographic projection of the columnar connection electrode 7 on the substrate, the negative effect of the columnar connection electrode 7 on the display effect of a local region can be adjusted based on a depth (that is, a thickness of remaining spacers 6 at the bottom position of the fracture DK) of the at least one fracture DK, thereby improving the display effect. In the display panel provided by one or more embodiments of the present disclosure, as shown in FIG. 33, a plurality of fractures DK are symmetrically distributed about a center of the sub-pixel.

In the embodiments of the present disclosure, by arranging the light emitting functional layers 4 in adjacent two first grooves C1 to communicate at the position of the fracture DK, and a plurality of fractures DK are symmetrically distributed about the center of the sub-pixel, when manufacturing the light emitting functional layer 4 of the display panel by using the inkjet printing process, it is more conducive to the leveling property of the material of the light emitting functional layer 4, and thus the thickness uniformity of the light emitting functional layers 4 in the same sub-pixel is further improved. In addition, when manufacturing the light emitting functional layer 4 of the display panel by using the inkjet printing process or the evaporation process, it is beneficial to the uniform distribution of the electrical properties of the light emitting functional layers 4 in the same sub-pixel, thereby improving the brightness uniformity and the luminous efficiency.

In the display panel provided by one or more embodiments of the present disclosure, the light emitting functional layer 4 includes a plurality of light emitting functional sublayers sequentially arranged in a direction away from the driving substrate 1, and a curvature of surfaces of the plurality of light emitting functional sublayers on the side away from the driving substrate 1, gradually decreases in a direction away from the first electrode 2.

It should be noted that in the embodiments of the present disclosure, the curvature refers to an average curvature, which will not be described in detail later.

In some exemplary embodiments, the plurality of light emitting functional sublayers can include one or more light emitting sublayers, a hole injection layer (HIL), a hole transporting layer (HTL), an electron transporting layer (ETL) and an electron injection layer (EIL). When the light emitting functional layer 4 includes two or more light emitting sublayers, the plurality of light emitting functional sublayers can further include a charge generation layer (CGL).

For example, the material of the light emitting sublayers can be selected from pyrene derivatives, anthracene derivatives, fluorene derivatives, perylene derivatives, styrylamine derivatives, metal complexes, and the like.

For example, the material of the hole injection layer can include oxides such as molybdenum oxide, titanium oxide, vanadium oxide, rhenium oxide, ruthenium oxide, chromium oxide, zirconium oxide, hafnium oxide, tantalum oxide, silver oxide, tungsten oxide and manganese oxide.

For example, the material of the hole injection layer can also include organic materials such as hexacyanohexaazatriphenylene, 2,3,5,6-tetrafluoro-7,7,8,8-tetracyanoquinodimethane (F4TCNQ), 1, 2, 3-tris|(cyano)(4-cyano-2,3,5,6-tetrafluorophenyl)methylene|cyclopropane.

For example, the material of the hole transporting layer can include aromatic amines and dimethylfluorene, or carbazole materials with hole transporting properties, for example, 4,4′-bis[N-(1-naphthyl)-N-phenylamino]biphenyl (NPB), N,N′-bis(3-methylphenyl)-N, N′-diphenyl-[1,1′-biphenyl]-4,4′-diamine (TPD), 4-phenyl-4′-(9-phenylfluoren-9-yl) triphenylamine (BAFLP), 4,4′-bis[N-(9,9-dimethylfluorene-2-yl)-N-phenylamino]biphenyl (DFLDPBi), 4,4′-bis(9-carbazolyl) biphenyl (CBP) and 9-phenyl-3-[4-(10-phenyl-9-anthryl)phenyl]-9H-carbazole (PCzPA).

For example, the material of the electron transporting layer can include aromatic heterocyclic compounds such as benzimidazole derivatives, imidazole derivatives, pyrimidine derivatives, zinc derivatives, quinoline derivatives, isoquinoline derivatives, phenanthroline derivatives, and the like.

For example, the material of the electron injection layer can be alkali metal or metal and compounds thereof, for example, lithium fluoride (LiF), ytterbium (Yb), magnesium (Mg) and calcium (Ca).

In the display panel provided by one or more embodiments of the present disclosure, as shown in FIG. 2 to FIG. 6, FIG. 10 and FIG. 11, FIG. 16A to FIG. 19 and FIG. 21 to FIG. 23, the sub-pixel includes a second electrode 5 covering the light emitting functional layer 4, and an average curvature of the second electrode 5 is less than an average curvature of the light emitting functional layer 4, and a refractive index of the second electrode 5 is less than a refractive index of the light emitting functional layer 4.

In some examples, the second electrode 5 can use any one or more of metal materials such as magnesium (Mg), silver (Ag) and aluminum (Al), or alloys made of any one or more of the above metals, or transparent conductive materials. A plurality of sub-pixels can share the second electrode 5.

In some exemplary embodiments, the refractive index of the light emitting functional layer 4 is in a range of 1.7 to 1.9, and the refractive index of the second electrode 5 is less than 1.7.

For example, the refractive index of the light emitting functional layer 4 can be 1.8, 1.85 or 1.9. The refractive index of the second electrode 5 can be 1.65, 1.52, 1.48 or 1.4.

In the embodiments of the present disclosure, by setting the refractive index of the second electrode 5 to be less than the refractive index of the light emitting functional layer 4, a refraction angle of the light decreases and converges when the light is emitted from the light emitting functional layer 4 through the second electrode 5, so that the light can be concentrated, thereby improving the luminous efficiency and the brightness.

In the display panel provided by one or more embodiments of the present disclosure, as indicated by the dotted line marked on the light emitting functional layer 4 in FIG. 2, in the first groove C1, a partial region (that is, the first cambered surface HM1) of the surface of the light emitting functional layer 4 on the side away from the driving substrate 1 is parallel to a surface of the first electrode 2 on the side away from the driving substrate 1.

A ratio of an area (that is, an area of a region indicated by the dotted line marked on the light emitting functional layer 4 in FIG. 2) of a part of the surface (that is, in the first cambered surface HM1) of the light emitting functional layer 4 on the side away from the driving substrate 1 that is parallel to a surface of the first electrode 2 on the side away from the driving substrate 1 to an area of the surface of the light emitting functional layer 4 on the side away from the driving substrate 1 is less than or equal to 20%.

In some exemplary embodiments, the part of the surface of the light emitting functional layer 4 on the side away from the driving substrate 1 that is parallel to the surface of the first electrode 2 on the side away from the driving substrate 1 can be set in the middle region of the first groove C1, and remaining surfaces of the light emitting functional layer 4 in the first groove C1 can be set in the edge region. In this way, for the light emitting functional layer 4 in the middle region, a distance between the light emitting functional layer 4 and the second electrode 2 in the direction perpendicular to the plane where the driving substrate 1 is located is equal, that is, the distance between the part of the first cambered surface HM1 located in the middle region and the second electrode 2 in the direction perpendicular to the plane where the driving substrate 1 is located is equal. At this time, taking the surface of the first electrode 2 on the side away from the driving substrate 1 as a plane as an example for explanation.

Of course, for the light emitting functional layer 4 in the middle region, a distance between the light emitting functional layer 4 and the driving substrate 1 in the direction perpendicular to the plane where the driving substrate 1 is located is equal, that is, the distance between the part of the first cambered surface HM1 located in the middle region and the driving substrate 1 in the direction perpendicular to the plane where the driving substrate 1 is located is equal.

In some embodiments, for the light emitting functional layer 4 in the edge region, in a direction from the middle region to the edge region, a distance between the light emitting functional layer 4 and the second electrode 2 gradually decreases in the direction perpendicular to the plane where the driving substrate 1 is located. At this time, taking the surface of the first electrode 2 on the side away from the driving substrate 1 as a plane as an example for explanation.

Of course, for the light emitting functional layer 4 in the edge region, in a direction from the middle region to the edge region, a distance between the light emitting functional layer 4 and the driving substrate 1 gradually decreases in the direction perpendicular to the plane where the driving substrate 1 is located.

When the surface of the first electrode 2 on the side away from the driving substrate J is a cambered surface, a distance relationship between the first cambered surface HM1 and the first electrode may not necessarily satisfy the above situation.

In the display panel provided by one or more embodiments of the present disclosure, as shown in FIG. 3 or FIG. 4, a ratio between a size d1 of the pixel opening K in a direction parallel to the plane where the driving substrate 1 is located and a distance d3 between adjacent two first electrodes 2 in the same direction has a range of 0.7 to 1.4, that is, a range of d1/d3 is from 0.7 to 1.4.

In some exemplary embodiments, the range of d1/d3 can be 0.8, 0.9, 1.0, 1.1, 1.2 or 1.3.

For example, the size d1 of the pixel opening K in the direction parallel to the plane where the driving substrate 1 is located is approximately equal to the distance d3 between adjacent two first electrodes 2 in the same direction.

In the display panel provided by the embodiment of the present disclosure, by setting the ratio between the size d1 of the pixel opening K in the direction parallel to the plane where the driving substrate 1 is located and the distance d3 between adjacent two first electrodes 2 in the same direction to be in the range of 0.7 to 1.4, that is, the range of d1/d3 is from 0.7 to 1.4, the size of the pixel opening K can be increased as much as possible (that is, an aperture ratio can be increased), and the distance between adjacent two first electrodes 2 can be reduced (that is, the distance between adjacent two sub-pixels can be reduced) under the manufacturing process of the current display panel, thereby improving the brightness of the display panel as much as possible and the resolution of the display panel, which is beneficial for manufacturing high-resolution display products.

In the display panel provided by one or more embodiments of the present disclosure, as shown in FIG. 4, FIG. 6 and FIG. 7, a surface of the first electrode 2 on the side away from the driving substrate 1 includes one or more second cambered surfaces HM2, an orthographic projection of the first cambered surface HM1 on a substrate of the driving substrate 1 is located within an orthographic projection of the second cambered surfaces HM2 on the substrate, and an orientation of the first cambered surface HM1 and an orientation of the second cambered surface HM2 are opposite.

In some exemplary embodiments, when the surface of the first electrode 2 on the side away from the driving substrate 1 includes the second cambered surface HM2, and the orientations of the first cambered surface HM1 and the second cambered surface HM2 are opposite, in each first groove C1, the distance between the part of the first cambered surface HM1 located in the middle region and the second cambered surface HM2 in the direction perpendicular to the plane where the driving substrate 1 is located is greater than the distance between the part of the first cambered surface HM1 located in the edge region and the second cambered surface HM2 in the direction perpendicular to the plane where the driving substrate 1 is located; and compared with the case where the surface of the first electrode 2 on the side away from the driving substrate 1 is a plane, the distance between the part of the first cambered surface HM1 located in the middle region and the second cambered surface HM2 in the direction perpendicular to the plane where the driving substrate 1 is located is greater.

In addition, when the surface of the first electrode 2 on the side away from the driving substrate 1 includes the second cambered surface HM2, and the orientations of the first cambered surface HM1 and the second cambered surface HM2 are opposite, the microcavity effect of each sub-pixel can be significantly improved, and the brightness of the sub-pixel can be significantly improved under the action of microcavity effect. An effective cavity length of microcavity effect is mainly determined by a distance between the first electrode 2 and the second electrode 5 and an effective refractive index N between the first electrode 2 and the second electrode 5. When the material is determined, the effective cavity length of microcavity effect is mainly determined by the distance d between the first electrode 2 and the second electrode 5.

It should be noted that when the surface of the first electrode 2 on the side away from the driving substrate 1 includes the second cambered surface HM2, and the orientations of the first cambered surface HM1 and the second cambered surface HM2 are opposite, compared with the case where the surface of the first electrode 2 on the side away from the driving substrate 1 is the plane, a distance between the first electrode 2 and the second electrode 5 is significantly increased.

In the display panel provided by one or more embodiments of the present disclosure, as shown in FIG. 4, FIG. 6 and FIG. 7, the second cambered surface HM2 serves as a bottom of the pixel opening K.

Taking the structure shown in FIG. 4 as an example, an area S2 of a region surrounded by an orthographic projection of an outer contour of the second cambered surface HM2 on the driving substrate 1 is greater than an area S1 of a region surrounded by an orthographic projection of an outer contour of edges of the pixel opening K. As shown in FIG. 7, sidewalls of the pixel opening K are provided with undercuts 8 at positions proximate to the second cambered surface HM2.

In the embodiments of the present disclosure, the sidewalls of the pixel opening K of each sub-pixel are provided with the undercuts 8 at positions proximate to the second cambered surface HM2, In the process of manufacturing the light emitting functional layer 4, the light emitting functional layers 4 in adjacent two sub-pixels can be well disconnected through the undercuts 8, thereby effectively blocking adjacent two sub-pixels and avoiding light crosstalk between adjacent two sub-pixels.

In some embodiments, as shown in FIG. 4, FIG. 6 and FIG. 7, the area S2 of the region surrounded by the orthographic projection of the outer contour of the second cambered surface HM2 on the driving substrate 1 is greater than the area S1 of the region surrounded by the orthographic projection of the outer contour of edges of the first groove C1 on the driving substrate 1, and at least part of sidewalls of the first groove C1 are provided with the undercuts 8 at positions proximate to the second cambered surface HM2, in this way, the light emitting functional layers 4 in adjacent two first grooves C1 in the same pixel opening K can be disconnected, and thus the light emitting functional layers 4 in adjacent two first grooves C1 are prevented from being connected together to destroy a structure similar to a convex lens of the first cambered surface HM1 in the first groove C1, thereby improving the yield of forming the first cambered surface HM1, and improving the light gathering effect of the light emitting functional layers 4 in the first groove C1. In addition, there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display panel to a great extent, and further improving the display effect.

In the display panel provided by one or more embodiments of the present disclosure, as shown in FIG. 4, FIG. 6 and FIG. 7, a curvature of the second cambered surface HM2 is less than a curvature of the first cambered surface HM1.

In the embodiments of the present disclosure, by setting the curvature of the second cambered surface HM2 to be less than the curvature of the first cambered surface HM1, the microcavity effect can be improved, and at the same time, the over-large undercuts 8 at the sidewalls of the first groove C1 (or at the sidewalls of the pixel opening K) caused by the over-large curvature of the second cambered surface HM2 can be avoided, thereby avoiding adverse problems such as the collapse of the spacers 6 or the pixel definition layer 3 caused by the over-large undercuts 8.

In the display panel provided by one or more embodiments of the present disclosure, as shown in FIG. 16A, FIG. 16B, FIG. 17 and FIG. 18, the pixel definition layer 3 includes the plurality of pixel openings K and one or more pixel recessed portions ZD located between adjacent two of the plurality of pixel openings K. Each of the pixel recessed portions ZD is provided with a second groove C2, where a region surrounded by an orthographic projection of an outer contour of the second groove C2 on the driving substrate 1 falls into a region surrounded by an orthographic projection of an outer contour of a gap between adjacent two first electrodes 2 on the driving substrate 1.

It should be noted that the above “adjacent two pixel openings” means that there are no other pixel openings arranged between two pixel openings K.

In the display panel provided by the embodiments of the present disclosure, by arranging the second groove C2 between adjacent sub-pixels, a part of the light emitting functional sublayers in the light emitting functional layers 4 of adjacent sub-pixels can be disconnected (not contacted) at the position of the second groove C2, thereby avoiding light crosstalk between adjacent two sub-pixels. The light emitting functional sublayers disconnected at the position of the second groove C2 include at least one of other film layers except a common layer in the light emitting functional sublayers, and the common layer of all sub-pixels in the display panel can be shared, that is, the common layers of any adjacent two sub-pixels are connected into a whole.

In some embodiments, for a display panel structure in which the light emitting functional layer 4 includes two or more light emitting sublayers, the second groove C2 can make the charge generation layers in the light emitting functional layers 4 of adjacent sub-pixels disconnect at the position where the second groove C2 is located, thereby avoiding crosstalk between adjacent sub-pixels caused by the charge generation layers with higher conductivity. In addition, since the display panel can avoid the crosstalk between adjacent sub-pixels through the second groove C2, the display panel can improve the pixels per inch while adopting a double-layer luminescence (Tandem EL) design. Therefore, the display panel has advantages such as long service life, low power consumption, high brightness and high resolution.

The charge generation layer can include an n-type doped layer for generating holes and a p-type doped layer for generating electrons which are stacked.

For example, the charge generation layer can include an n-type doped organic layer/a p-doped organic layer such as BPhen:Cs/NPB:F4-TCNQ, Alq₃:Li/NPB:FeCl₃, TPBi:Li/NPB:FeCl₃ and Alq₃:Mg/m-MTDATA:F4-TCNQ. Of course, the embodiments of the present disclosure include but are not limited to this, and the material of the charge generation layer can also include an n-type doped organic layer/an inorganic metal oxide such as Alq₃:Mg/WO₃, Bphen:Li/MoO₃, BCP:Li/V₂O₅ and BCP:Cs/V₂O₅; alternatively, an n-type doped organic layer/an organic layer such as Alq₃:Li/HAT-CN; alternatively, undoped materials such as F₁₆CuPe/CuPe and Al/WO₃/Au.

In the embodiments of the present disclosure, when manufacturing the light emitting functional layer 4 by using the inkjet printing process, when the printing ink deviates, the printing ink flows into the second groove C2, in this way, color mixing of the printing ink in adjacent two sub-pixels can be avoided.

In the display panel provided by one or more embodiments of the present disclosure, as shown in FIG. 16A, FIG. 16B, FIG. 17 and FIG. 18, a ratio between a maximum size d2 of the second groove C2 in a direction parallel to the plane where the driving substrate 1 is located and a depth h2 of the second groove C2 in a direction perpendicular to the plane where the driving substrate 1 is located is less than a ratio between a maximum size d1 of the first groove C1 in a direction parallel to the plane where the driving substrate 1 is located and a depth h1 of the first groove C1 in a direction perpendicular to the plane where the driving substrate 1 is located, that is, d2/h2<d1/h1.

In some embodiments, since the light emitting functional layer 4 in the first groove C1 is located in the pixel opening area, that is, a region actually used for emitting light in the display panel, and the second groove C2 is mainly used to space adjacent two sub-pixels, an actual size (including width and/or depth) of the second groove C2 can be set to be less than an actual size of the first groove C1. In practical applications, in order to facilitate manufacturing, the depths of the first groove C1 and the second groove C2 can be set to be the same, and a size relationship between d2/h2 and d1/h1 can be adjusted by adjusting the width.

In some embodiments, the ratio between the maximum size d2 of the second groove C2 in the direction parallel to the plane where the driving substrate 1 is located and the depth h2 of the second groove C2 in the direction perpendicular to the plane where the driving substrate 1 is located is equal to the ratio between the maximum size d1 of the first groove C1 in a direction parallel to the plane where the driving substrate 1 is located and the depth h1 of the first groove C1 in the direction perpendicular to the plane where the driving substrate 1 is located, that is, d2/h2=d1/h1.

In the embodiments of the present disclosure, by setting d2/h2≤d1/h1, a depth-width ratio of the second groove C2 is greater than a depth-width ratio of the first groove C1, which is more beneficial to the curvature of the light emitting functional layer 4 manufactured in the second groove C2 being greater than the curvature of the light emitting functional layer 4 in the first groove C1 in the subsequent process, thereby improving the light convergence effect of the light emitting functional layer 4 in the first groove C1 in the pixel opening K, and further improving the convergence effect of the light emitting functional layer 4 in the second groove C2 on crosstalk light (see the explanation later), improving the crosstalk problem of light, improving the brightness of the display panel, and improving the display effect of the display panel.

In the display panel provided by one or more embodiments of the present disclosure, as shown in FIG. 16A, FIG. 16B, FIG. 17 and FIG. 18, the second groove C2 divides the same pixel recessed portion ZD into two parts (including ZD1 and ZD2).

In the same direction parallel to the plane where the driving substrate 1 is located, a ratio between a size (d4 or d4′) of a part of the pixel recessed portion and a size d2 of the second groove C2 has a range of 0.7 to 1.4. That is, a ratio of d4/d2 has a range of 0.7 to 1.4, or a ratio of d4′/d2 has a range of 0.7 to 1.4.

For example, the pixel recessed portion ZD includes a first pixel recessed portion ZD1 and a second pixel recessed portion ZD2, where a ratio between a size d4 of the first pixel recessed portion ZD1 and the size d2 of the second groove C2 has a range of 0.7 to 1.4.

For example, the pixel recessed portion ZD includes a first pixel recessed portion ZD1 and a second pixel recessed portion ZD2, where a ratio between a size d4′ of the second pixel recessed portion ZD2 and the size d2 of the second groove C2 has a range of 0.7 to 1.4.

For example, in the same direction parallel to the plane where the driving substrate 1 is located, the ratio between the size (d4 or d4′) of a part of the pixel recessed portion and a size d2 of the second groove C2 can be 0.8, 0.9, 1.0, 1.1, 1.2 or 1.3.

In the display panel provided by one or more embodiments of the present disclosure, as shown in FIG. 16A, FIG. 16B, FIG. 17 and FIG. 18, an absolute value of a difference between a ratio (that is d4/d2 or d4′/d2) between the size (d4 or d4′) of the part of the pixel recessed portion ZD in the direction parallel to the plane where the driving substrate 1 is located and a size d2 of the second groove C2 in the same direction and a ratio (that is, d1/d3) between a size d1 of the pixel opening K in the direction parallel to the plane where the driving substrate 1 is located and a distance d3 between adjacent two first electrodes 2 in the same direction is less than or equal to 0.1.

That is, |d4/d2−d1/d3|≤0.1 or |d4′/d2−d1/d3|≤0.1.

For example, |d4/d2−d1/d3| can be equal to 0.03, 0.05, 0.08 or 0.09.

For example, |d4′/d2−d1/d3| can be equal to 0.03, 0.05, 0.08 or 0.09.

In the embodiments of the present disclosure, by setting |d4/d2−d1/d3|≤0.1 or |d4′/d2−d1/d3|≤0.1, the manufacturing process accuracy and the size accuracy of the second electrode 2 in adjacent two sub-pixels can be improved, and the manufacturing process accuracy and the size accuracy of the pixel opening K and the pixel recessed portion ZD in the pixel definition layer 3 can be improved, thereby improving the utilization rate of the space, and facilitating the manufacture of display panels with high precision and high pixels per inch (PPI).

In the display panel provided by one or more embodiments of the present disclosure, as shown in FIG. 16A, FIG. 16B, FIG. 17 and FIG. 18, an absolute value of a size difference 20) (d3−d3′) between adjacent two gaps (gaps between two first electrodes 2) is less than an absolute value of a size difference (d4−d4′) between two parts. (ZD1 and ZD2) on the same pixel recessed portion ZD in the same direction parallel to the plane where the driving substrate 1 is located, that is, |d3−d3′|<|d4−d4′|.

In the embodiments of the present disclosure, by setting |d3−d3′|<|d4−d4′, the manufacturing process accuracy and the size accuracy of the second electrode 2 in adjacent two sub-pixels are greater than the manufacturing process accuracy and the size accuracy of the pixel opening K and the pixel recessed portion ZD in the pixel definition layer 3.

In the display panel provided by one or more embodiments of the present disclosure, the plurality of sub-pixels include a first sub-pixel, a second sub-pixel and a third sub-pixel, and display colors of the first sub-pixel, the second sub-pixel and the third sub-pixel are different.

For example, one of the first sub-pixel, the second sub-pixel and the third sub-pixel is a red sub-pixel, the other is a green sub-pixel, and the remaining one is a blue sub-pixel.

In the direction parallel to the plane where the driving substrate 1 is located, an absolute value of a size difference (d3−d3′) between a gap between the first sub-pixel and the second sub-pixel (a gap between the first electrode 2 of the first sub-pixel and the first electrode 2 of the second sub-pixel) and a gap between the second sub-pixel and the third sub-pixel (a gap between the first electrode 2 of the second sub-pixel and the first electrode 2 of the third sub-pixel) is less than an absolute value of a size difference between a size (d2) of a second groove C2 between the first sub-pixel and the second sub-pixel and a size (d2′) of a second groove C2 between the second sub-pixel and the third sub-pixel, that is, |d3−d3′|<|d2−d2′|.

An absolute value of a size difference (d3−d3′) between a gap between the second sub-pixel and the third sub-pixel (a gap between the first electrode 2 of the second sub-pixel and the first electrode 2 of the third sub-pixel) and a gap between the third sub-pixel and the first sub-pixel (a gap between the first electrode 2 of the third sub-pixel and the first electrode 2 of the first sub-pixel) is less than an absolute value of a size difference between a size (d2) of the second groove C2 between the second sub-pixel and the third sub-pixel and a size (d2′) of the second groove C2 between the third sub-pixel and the first sub-pixel, that is, |d3−d3′|<|d2−d2′|.

In the embodiments of the present disclosure, by setting |d3−d3′|<|d2−d2′|, the manufacturing process accuracy and the size accuracy of the second electrode 2 in adjacent two sub-pixels are greater than the manufacturing process accuracy and the size accuracy of the pixel opening K and the pixel recessed portion ZD in the pixel definition layer 3.

In the display panel provided by one or more embodiments of the present disclosure, in the direction parallel to the plane where the driving substrate 1 is located, the absolute value of the size difference (d3−d3′) between the gap between the first sub-pixel and the second sub-pixel (the gap between the first electrode 2 of the first sub-pixel and the first electrode 2 of the second sub-pixel) and the gap between the second sub-pixel and the third sub-pixel (the gap between the first electrode 2 of the second sub-pixel and the first electrode 2 of the third sub-pixel) is less than an absolute value of a size difference (d8−d8′) between a size d8 of a pixel recessed portion ZD between the first sub-pixel and the second sub-pixel and a size d8′ of a pixel recessed portion ZD between the second sub-pixel and the third sub-pixel, that is, |d3−d3′|<|d8−d8′|.

In the direction parallel to the plane where the driving substrate 1 is located, the absolute value of the size difference (d3−d3′) between the gap between the second sub-pixel and the third sub-pixel (the gap between the first electrode 2 of the second sub-pixel and the first electrode 2 of the third sub-pixel) and the gap between the third sub-pixel and the first sub-pixel (the gap between the first electrode 2 of the third sub-pixel and the first electrode 2 of the first sub-pixel) is less than an absolute value of a size difference (d8−d8′) between a size d8 of the pixel recessed portion ZD between the second sub-pixel and the third sub-pixel and a size d8′ of a pixel recessed portion ZD between the third sub-pixel and the first sub-pixel, that is, |d3−d3′|<|d8−d8′|.

In the embodiments of the present disclosure, by setting |d3−d3′|<|d8−d8′|, the manufacturing process accuracy and the size accuracy of the second electrode 2 in adjacent two sub-pixels are greater than the manufacturing process accuracy and the size accuracy of the pixel opening K and the pixel recessed portion ZD in the pixel definition layer 3.

In the display panel provided by one or more embodiments of the present disclosure, as shown in FIG. 16B to FIG. 18, a partial region of the light emitting functional layer 4 is arranged in the second groove C2 and on a surface of the pixel recessed portion ZD on a side away from the driving substrate 1, and a part of the surface of the light emitting functional layer 4 on the side away from the driving substrate 1 located in the second groove C2 includes a third cambered surface HM3, and a curvature of the first cambered surface HM1 is less than a curvature of the third cambered surface HM3.

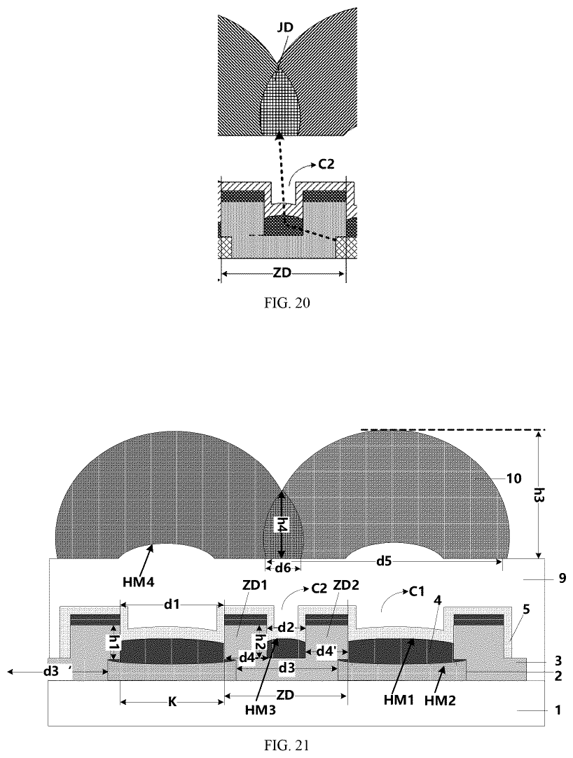

As shown in FIG. 20, when the part of the surface of the light emitting functional layer 4 on the side away from the driving substrate 1 located in the second groove C2 includes the third cambered surface HM3, since the third cambered surface HM3 forms a structure similar to a convex lens, when crosstalk lights in adjacent two sub-pixels are laterally emitted and irradiated to the light emitting functional layer 4 in the second groove C2, the third cambered surface HM3 can gather the crosstalk lights and irradiate the crosstalk lights to a light shielding area (for example, a light shielding pattern described later, or an overlap area formed between adjacent two color film patterns, see the description below for details), and the light shielding area can absorb the crosstalk lights, thereby avoiding the crosstalk lights from being emitted from the display panel and improving the display effect of the display panel.

For example, in a direction that a central region of the third cambered surface HM3 points a periphery of the third cambered surface HM3, a distance between the third cambered surface HM3 and the driving substrate 1 gradually decreases.

Of course, for the third cambered surface HM3, the partial region of the third cambered surface HM3 can be arranged to be parallel to the surface of the first electrode 2 on the side away from the driving substrate 1 (or the partial region of the third cambered surface HM3 can be arranged to be parallel to the driving substrate 1), that is, the partial region of the third cambered surface HM3 can also include a structure similar to a plane, and thus the third cambered surface HM3 is called a structure similar to a convex lens, rather than a strictly defined convex lens structure.

In the display panel provided by one or more embodiments of the present disclosure, as shown in FIG. 2 to FIG. 6. FIG. 10 and FIG. 11, FIG. 16A to FIG. 19 and FIG. 21 to FIG. 23, the curvature of the first cambered surface HM1 is greater than the curvature of the part of the surface of the light emitting functional layer 4 away from the driving substrate 1 arranged in the pixel recessed portion ZD.

By setting the curvature of the first cambered surface HM1 to be greater than the curvature of the part of the surface of the light emitting functional layer 4 away from the driving substrate 1 arranged in the pixel recessed portion ZD, the light emitting surface of the light emitting functional layer 4 in each first groove C1 in the pixel opening K can form a structure similar to a convex lens, and has a better light gathering effect, and there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display panel to a great extent, and further improving the display effect.

In some exemplary embodiments, as shown in FIG. 16B to FIG. 18, the curvature of the third cambered surface HM3 is greater than the curvature of the part of the surface of the light emitting functional layer 4 away from the driving substrate 1 arranged in the pixel recessed portion ZD.

In the display panel provided by one or more embodiments of the present disclosure, the curvature of the light emitting functional layer of at least one of the first sub-pixel and the second sub-pixel is greater than the curvature of the light emitting functional layer of the third sub-pixel.

For example, the curvature of the light emitting functional layer of the first sub-pixel is greater than the curvature of the light emitting functional layer of the third sub-pixel.

For example, the curvature of the light emitting functional layer of the second sub-pixel is greater than the curvature of the light emitting functional layer of the third sub-pixel.

In the display panel provided by one or more embodiments of the present disclosure, an area of a light emitting area of the first sub-pixel is less than an area of a light emitting area of the second sub-pixel, and the area of the light emitting area of the second sub-pixel is less than an area of a light emitting area of the third sub-pixel; and the curvature of the light emitting functional layer 4 of the first sub-pixel is greater than the curvature of the light emitting functional layer 4 of the second sub-pixel, and the curvature of the light emitting functional layer 4 of the second sub-pixel is greater than the curvature of the light emitting functional layer 4 of the third sub-pixel.

That is, the smaller the area of the light emitting area in the sub-pixel, the greater the curvature of the light emitting functional layer 4 in the pixel opening K of the sub-pixel.

In the embodiments of the present disclosure, by setting the curvature of the light emitting functional layer 4 in the sub-pixel with the smaller light emitting area to be larger, the brightness difference caused by the relatively small area of the light emitting functional layer 4 can be compensated by the light gathering effect of the first cambered surface HM1 formed by the light emitting functional layer 4, thereby improving the brightness of each sub-pixel with different light emitting areas, and further improving the display effect of the display panel.

In the display panel provided by one or more embodiments of the present disclosure, as shown in FIG. 19 to FIG. 23; the sub-pixel includes a second electrode 5, an encapsulation layer 9 and one or more color film patterns 10, where the second electrode 5 covers the light emitting functional layer 4; the encapsulation layer 9 covers the second electrode 5, and the color, film patterns 10 are located on a side of the encapsulation layer 9 away from the second electrode 5.

As indicated by markings in FIG. 19, a fourth cambered surface HM4 is arranged at a part of the encapsulation layer 9 overlapping with the orthographic projection of the first cambered surface HM1 on the driving substrate 1, wherein a curvature of the fourth cambered surface HM 4 is less than the curvature of the first cambered surface HM1.

In some exemplary embodiments, a refractive index of the color film patterns 10 is greater than a refractive index of the encapsulation layer 9.

The material of the color film patterns 10 includes organic materials such as resin, and the material of the encapsulation layer 9 includes at least inorganic materials (including only inorganic materials, or both organic materials and inorganic materials). In general, a refractive index of the organic materials is greater than a refractive index of the inorganic materials, and thus the refractive index of the color film patterns 10 is greater than the refractive index of the encapsulation layer 9.

In the embodiments of the present disclosure, by arranging the fourth cambered surface HM4 on the encapsulation layer 9, the fourth cambered surface HM4 can further converge the light emitted by the sub-pixels, thereby improving the luminous efficiency and the brightness of the display panel, and further improving the display effect.

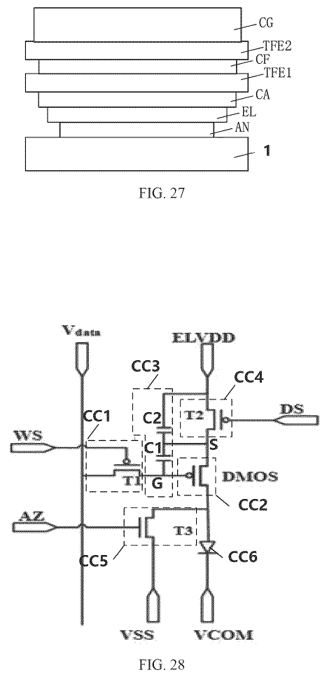

It should be noted that in the structures shown in FIG. 19 to FIG. 23, FIG. 25 and FIG. 26, the color film patterns 10 (or labeled as CF-R, CF-G, CF-B) is located on the side of the encapsulation layer 9 away from the second electrode 5. In other embodiments, as shown in FIG. 27, the encapsulation layer 9 can include two encapsulation sublayers (TFE1 and TFE2), and the color film patterns 10 (CF) can be arranged between the two encapsulation sublayers. At this time, the fourth cambered surface HM4 described above can be arranged on both encapsulation sublayers.

In the display panel provided by one or more embodiments of the present disclosure, as shown in FIG. 19 to FIG. 23, the color film patterns 10 include a lens structure, where the lens structure covers the fourth cambered surface HM4, and an orthographic projection of the color film patterns 10 on the driving substrate 1 covers the orthographic projection of the first cambered surface HM1 on the driving substrate 1′.

For example, colors of a plurality of color film patterns 10 are not completely the same. For example, the colors of the plurality of color film patterns 10 can be set according to the display colors of the sub-pixels, that is, the colors of the plurality of color film patterns 10 can be set to the same as the display colors of the sub-pixels.

The color film patterns 10 are also called color filters.

For example, the plurality of color film patterns 10 can include red color film patterns, green color film patterns and blue color film patterns.

In the display panel provided by one or more embodiments of the present disclosure, as shown in FIG. 23, one or more light shielding patterns (for example, one or more black matrix patterns BM) are arranged between the color film patterns 10 of adjacent two sub-pixels, and a partial region of the color film patterns 10 is arranged on a side of the light shielding patterns away from the driving substrate 1, that is, the color film patterns 10 on both sides of the light shielding pattern can partially overlap on the side of the light shielding patterns away from the driving substrate 1.

The region surrounded by the orthographic projection of the outer contour of the second groove C2 on the driving substrate 1 falls within an orthographic projection of the light shielding patterns BM on the driving substrate 1.

When the region surrounded by the orthographic projection of the outer contour of the second groove C2 on the driving substrate 1 falls within an orthographic projection of the light shielding patterns BM on the driving substrate 1, a region surrounded by an orthographic projection of the third cambered surface HM3 formed by the light emitting functional layer 4 in the second groove C2 falls within the orthographic projection of the light shielding patterns BM on the driving substrate 1. In this way, after the crosstalk lights are converged by the third cambered surface HM3, these crosstalk lights can be irradiated on the light shielding patterns BM, thereby avoiding the crosstalk lights from being emitted from the display panel, improving the problem of light crosstalk, and improving the display effect of the display panel.

For example, as shown in FIG. 23, in the direction parallel to the plane where the driving substrate 1 is located, a size d6 of the light shielding patterns BM is greater than or equal to the size d2 of the second groove C2, so that the crosstalk lights can be irradiated to the light shielding patterns BM after being converged by the third cambered surface HM3, thereby enabling the light shielding patterns BM to absorb the crosstalk lights as completely as possible.

In the display panel provided by one or more embodiments of the present disclosure, as shown in FIG. 19 to FIG. 21, there is an overlap area JD between the color film patterns 10 of adjacent two sub-pixels, and the region surrounded by the orthographic projection of the outer contour of the second groove C2 on the driving substrate 1 falls within an orthographic projection of the overlap area JD on the driving substrate 1.

In some exemplary embodiments, the colors of the color film patterns 10 of adjacent two sub-pixels are different, and when the colors of the color film patterns 10 of adjacent two sub-pixels are different, the overlap area JD can play a role in shading.

When the region surrounded by the orthographic projection of the outer contour of the second groove C2 on the driving substrate 1 falls within the orthographic projection of the overlap area JD on the driving substrate 1, the region surrounded by the orthographic projection of the third cambered surface HM3 formed by the light emitting functional layer 4 in the second groove C2 falls within the orthographic projection of the overlap area JD on the driving substrate 1. In this way, after the crosstalk lights are converged by the third cambered surface HM3, these crosstalk lights can be irradiated on the overlap area JD, thereby avoiding the crosstalk lights from being emitted from the display panel, improving the problem of light crosstalk, and improving the display effect of the display panel.

For example, as shown in FIG. 19, in the direction parallel to the plane where the driving substrate 1 is located, a size d6 of the overlap area JD is greater than or equal to the size d2 of the second groove C2, so that the crosstalk lights can be irradiated to the light shielding patterns BM after being converged by the third cambered surface HM3, thereby enabling the light shielding patterns BM to absorb the crosstalk lights as completely as possible.

In the display panel provided by one or more embodiments of the present disclosure, as shown in FIG. 19 and FIG. 21 to FIG. 23, a height h3 of the color film patterns 10 in the direction perpendicular to the plane where the driving substrate 1 is located is greater than a width d5 of the color film patterns 10 in the direction parallel to the plane where the driving substrate 1 is located.

In some exemplary embodiments, the height h3 of the color film patterns 10 in the direction perpendicular to the plane where the driving substrate 1 is less than or equal to Sum. For example, a thickness of the color film patterns 10 can be 1.5 μm, 1.8 μm, 2.0 μm, 2.2 μm, 2.4 μm, 2.5 μm, 2.8 μm, 3.0 μm, 3.3 μm, 3.5 μm, 3.8 μm, 4.0 μm, 4.2 μm, 4.5 μm, 4.8 μm or 5.0 μm.

In the display panel provided by the embodiments of the present disclosure, by setting the height h3 of the color film patterns 10 in the direction perpendicular to the plane where the driving substrate 1 to be greater than the width d5 of the color film patterns 10 in the direction parallel to the plane where the driving substrate 1 is located, on the one hand, the color film patterns 10 with a lens structure can have a better light gathering effect; on the other hand, it indicates that the size of sub-pixels in the display panel is relatively small, which is suitable for manufacturing high pixels per inch (PPI) display products.

In the display panel provided by one or more embodiments of the present disclosure, as shown in FIG. 19, a height h4 of the overlap area JD between the color film patterns 10 of adjacent two sub-pixels in the direction perpendicular to the plane where the driving substrate 1 is located is greater than a width d5 of the color film patterns 10 in the direction parallel to the plane where the driving substrate 1 is located.

In some exemplary embodiments, by setting the height h4 of the overlap area JD between the color film patterns 10 of adjacent two sub-pixels in the direction perpendicular to the plane where the driving substrate 1 is located to be greater than the width d5 of the color film patterns 10 in the direction parallel to the plane where the driving substrate 1 is located, when the crosstalk lights irradiate the overlap area JD, the overlap area JD has a better absorption effect on the crosstalk lights (that is, the thicker the overlap area JD is, the better the light shielding effect is), thereby avoiding the crosstalk lights from being emitted from the display panel, improving the problem of light crosstalk, and improving the display effect of the display panel.

In some exemplary embodiments, the display panel can further include a buffer layer or a planarization layer. The buffer layer is used to cover a cathode (second electrode 5) to facilitate the subsequent deposition of the encapsulation layer 9, and the planarization layer is used for planarization.

The above display panel can also include other structures and components. This specification only introduces structures and components related to inventive points, and other structures and components included in this display panel can refer to the introduction in the related art.

The embodiments of the present disclosure provide a display device including the display panel as described in any one of the foregoing.

The specific structure of the display panel can refer to the previous introduction, and will not be described here.

For example, FIG. 27 shows a schematic simplified structural diagram of a display device. The display device further includes a cover plate CG.

The display device provided by the embodiments of the present disclosure can be an OLED display device. The OLED display device can include a glass-based OLED display device and a silicon-based OLED display device.

In addition, the display device can be a display device such as an OLED display, and any product or component with display function such as a TV, a digital camera, a mobile phone, a tablet computer, and the like including these display devices.

In the display device provided by the embodiments of the present disclosure, since in each first groove C1, as indicated by markings in FIG. 2, the distance J1 between the part of the first cambered surface HM1 located in the middle region and the driving substrate 1 is greater than the distance J2 between the part of the first cambered surface HM1 located in the edge region and the driving substrate 1 in the direction perpendicular to the plane where the driving substrate 1 is located, each first cambered surface HM1 in the first groove C1 can form a structure similar to a convex lens, and thus the light emitted by the light emitting functional layer 4 is converged within the range of the first groove C1, and there is no need to additionally arrange a microlens array structure on a light emitting side of the light emitting side of light emitting functional layers of sub-pixels, thereby saving the process steps, avoiding the damage to the light emitting functional layers caused by the thermal reflow process of the microlens process in the related art, and at the same time, improving the luminous efficiency and the brightness of the display device to a great extent, and further improving the display effect.

The above is only the specific implementation of the present disclosure, but the protection scope of the present disclosure is not limited to this. Any skilled person familiar with this technical field can easily think of changes or replacements within the technical scope disclosed in the present disclosure, which should be covered within the protection scope of the present disclosure. Therefore, the protection scope of the present disclosure should be based on the protection scope of the claims.

1. A display panel, comprising a driving substrate and a plurality of sub-pixels arranged in an array on the driving substrate, wherein each of the plurality of sub-pixels comprises:
a pixel definition layer comprising a pixel opening, wherein the pixel opening comprises one or more first grooves;
a first electrode arranged between the pixel definition layer and the driving substrate, wherein a partial region of the first electrode serves as a bottom of the pixel opening; and
one or more light emitting functional layers at least arranged in the first grooves, wherein a part of a surface of the light emitting functional layers on a side away from the driving substrate located in the first grooves comprises a first cambered surface,
wherein the first groove comprises a middle region and an edge region surrounding the middle region, and in the first groove, a distance between a part of the first cambered surface located in the middle region and the driving substrate is greater than a distance between a part of the first cambered surface located in the edge region and the driving substrate in a direction perpendicular to a plane where the driving substrate is located.

2. The display panel according to claim 1, wherein a ratio between a depth of the pixel opening in the direction perpendicular to the plane where the driving substrate is located and a maximum size of the pixel opening in a direction parallel to the plane where the driving substrate is located is greater than or equal to 0.3.

3. The display panel according to claim 2, wherein the ratio between the depth of the pixel opening in the direction perpendicular to the plane where the driving substrate is located and the maximum size of the pixel opening in the direction parallel to the plane where the driving substrate is located is greater than or equal to 0.3 and less than or equal to 0.8.

4. The display panel according to claim 3, wherein the pixel opening comprises one of the first grooves, and a maximum size of the sub-pixel in the direction parallel to the plane where the driving substrate is located is less than or equal to 2 μm; or
wherein the pixel opening comprises two or more of the first grooves, and a maximum size of the sub-pixel in the direction parallel to the plane where the driving substrate is located is less than or equal to 2 μm.

5. (canceled)

6. The display panel according to claim 4, wherein the pixel opening further comprises one or more spacers located between adjacent two of the first grooves, and a ratio between a depth of the first groove in the direction perpendicular to the plane where the driving substrate is located and a maximum size of the first groove in the direction parallel to the plane where the driving substrate is located is greater than or equal to 0.3 and less than or equal to 0.8.

7. The display panel according to claim 6, wherein the ratio between the depth of the pixel opening in the direction perpendicular to the plane where the driving substrate is located and the maximum size of the pixel opening in the direction parallel to the plane where the driving substrate is located is greater than the ratio between the depth of the first groove in the direction perpendicular to the plane where the driving substrate is located and a maximum size of the first groove in the direction parallel to the plane where the driving substrate is located; or
wherein the spacers and the pixel definition layer are arranged in the same layer; or
wherein the spacers and the pixel definition layer are arranged in the same layer, wherein the first electrode comprises a plurality of contact portions and a plurality of protrusion portions, wherein one of the plurality of protrusion portions is arranged between adjacent two of the plurality of contact portions, the plurality of contact portions serve as a plurality of bottoms of the first grooves and the plurality of protrusion portions serve as the spacers.

8-10. (canceled)

11. The display panel according to claim 7, wherein the driving substrate comprises a plurality of columnar connection electrodes, and one or more of the plurality of columnar connection electrodes are in contact connection with the first electrode in the sub-pixel; and
an orthographic projection of the columnar connection electrodes on a substrate of the driving substrate is located within an orthographic projection of the plurality of protrusion portions on the substrate, and an end of the columnar connection electrodes away from the substrate protrudes from a surface of the driving substrate near the first electrode.

12. The display panel according to claim 11, wherein one or more fractures are arranged on the spacers, and one or more light emitting functional layers in adjacent two first grooves are communicated at positions of the fractures.

13. The display panel according to claim 12, wherein a depth of the fractures in the direction perpendicular to the plane where the driving substrate is located is less than or equal to a height of the spacers in the direction perpendicular to the plane where the driving substrate is located; or
wherein a region surrounded by an orthographic projection of an outer contour of at least one of the fractures on the substrate overlaps with the orthographic projection of the columnar connection electrodes on the substrate, or
wherein a plurality of fractures are symmetrically distributed about a center of the sub-pixel; or
wherein orthographic projection patterns of the spacers on the driving substrate comprise a ring shape or a grid shape.

14-16. (canceled)

17. The display panel according to claim 4, wherein the light emitting functional layer comprises a plurality of light emitting functional sublayers sequentially arranged in a direction away from the driving substrate, and a curvature of surfaces of the plurality of light emitting functional sublayers on the side away from the driving substrate gradually decreases in a direction away from the first electrode; or
wherein in the first groove, a partial region of the surface of the light emitting functional layer on the side away from the driving substrate is parallel to a surface of the first electrode on the side away from the driving substrate; and
a ratio of an area of a part of the surface of the light emitting functional layer on the side away from the driving substrate that is parallel to a surface of the first electrode on the side away from the driving substrate to an area of the surface of the light emitting functional layer on the side away from the driving substrate is less than or equal to 20%; or
wherein a ratio between a size of the pixel opening in a direction parallel to the plane where the driving substrate is located and a distance between adjacent two first electrodes in the same direction has a range of 0.7 to 1.4; or
wherein a surface of the first electrode on the side away from the driving substrate comprises one or more second cambered surfaces, wherein an orthographic projection of the first cambered surface on a substrate of the driving substrate is located within an orthographic projection of the second cambered surfaces on the substrate, and an orientation of the first cambered surface and an orientation of the second cambered surface are opposite.

18. The display panel according to claim 17, wherein the sub-pixel comprises a second electrode covering the light emitting functional layer, and an average curvature of the second electrode is less than an average curvature of the light emitting functional layer, and a refractive index of the second electrode is less than a refractive index of the light emitting functional layer.

19-23. (canceled)

24. The display panel according to claim 2, wherein the pixel definition layer comprises the plurality of pixel openings and one or more pixel recessed portions located between adjacent two of the plurality of pixel openings;
each of the pixel recessed portions is provided with a second groove, wherein a region surrounded by an orthographic projection of an outer contour of the second groove on the driving substrate falls into a region surrounded by an orthographic projection of an outer contour of a gap between adjacent two first electrodes on the driving substrate; and
a ratio between a maximum size of the second groove in a direction parallel to the plane where the driving substrate is located and a depth of the second groove in a direction perpendicular to the plane where the driving substrate is located is less than or equal to a ratio between a maximum size of the first groove in a direction parallel to the plane where the driving substrate is located and a depth of the first groove in a direction perpendicular to the plane where the driving substrate is located.

25. The display panel according to claim 24, wherein the second groove divides the same pixel recessed portion into two parts; and
a ratio between a size of a part of the pixel recessed portion and a size of the second groove has a range of 0.7 to 1.4 in the same direction parallel to the plane where the driving substrate is located; or
wherein a partial region of the light emitting functional layer is arranged in the second groove and on a surface of the pixel recessed portion on a side away from the driving substrate, and a part of the surface of the light emitting functional layer on the side away from the driving substrate located in the second groove comprises a third cambered surface, and a curvature of the first cambered surfaces is less than a curvature of the third cambered surface; or
wherein the sub-pixel comprises a second electrode, an encapsulation layer and one or more color film patterns, wherein the second electrode covers the light emitting functional layer, the encapsulation layer covers the second electrode, and the color film patterns are located on a side of the encapsulation layer away from the second electrode; and
a fourth cambered surface is arranged at a part of the encapsulation layer overlapping with the orthographic projection of the first cambered surface on the driving substrate, wherein a curvature of the fourth cambered surface is less than the curvature of the first cambered surface,
wherein the color film patterns comprise a lens structure, wherein the lens structure covers the fourth cambered surface, and an orthographic projection of the color film patterns on the driving substrate covers the orthographic projection of the first cambered surface on the driving substrate.

26. The display panel according to claim 25, wherein an absolute value of a difference between a ratio between the size of the part of the pixel recessed portion in the direction parallel to the plane where the driving substrate is located and a size of the second groove in the same direction and a ratio between a size of the pixel opening in the direction parallel to the plane where the driving substrate is located and a distance between adjacent two first electrodes in the same direction is less than or equal to 0.1; or
wherein an absolute value of a size difference between adjacent two gaps is less than an absolute value of a size difference between two parts on the same pixel recessed portion in the same direction parallel to the plane where the driving substrate is located.

27. (canceled)

28. The display panel according to claim 26, wherein the plurality of sub-pixels comprise a first sub-pixel, a second sub-pixel and a third sub-pixel, and display colors of the first sub-pixel, the second sub-pixel and the third sub-pixel are different;
in the direction parallel to the plane where the driving substrate is located, an absolute value of a size difference between a gap between the first sub-pixel and the second sub-pixel and a gap between the second sub-pixel and the third sub-pixel is less than an absolute value of a size difference between a second groove between the first sub-pixel and the second sub-pixel and a second groove between the second sub-pixel and the third sub-pixel; and
an absolute value of a size difference between a gap between the second sub-pixel and the third sub-pixel and a gap between the third sub-pixel and the first sub-pixel is less than an absolute value of a size difference between the second groove between the second sub-pixel and the third sub-pixel and a second groove between the third sub-pixel and the first sub-pixel.

29. The display panel according to claim 28, wherein in the direction parallel to the plane where the driving substrate is located, the absolute value of the size difference between the gap between the first sub-pixel and the second sub-pixel and the gap between the second sub-pixel and the third sub-pixel is less than an absolute value of a size difference between a pixel recessed portion between the first sub-pixel and the second sub-pixel and a pixel recessed portion between the second sub-pixel and the third sub-pixel; and
the absolute value of the size difference between the gap between the second sub-pixel and the third sub-pixel and the gap between the third sub-pixel and the first sub-pixel is less than an absolute value of a size difference between the pixel recessed portion between the second sub-pixel and the third sub-pixel and a pixel recessed portion between the third sub-pixel and the first sub-pixel; or
wherein the curvature of the light emitting functional layer of at least one of the first sub-pixel and the second sub-pixel is greater than the curvature of the light emitting functional layer of the third sub-pixel.

30-32. (canceled)

33. The display panel according to claim 29, wherein an area of a light emitting area of the first sub-pixel is less than an area of a light emitting area of the second sub-pixel, and the area of the light emitting area of the second sub-pixel is less than an area of a light emitting area of the third sub-pixel; and
the curvature of the light emitting functional layer of the first sub-pixel is greater than the curvature of the light emitting functional layer of the second sub-pixel, and the curvature of the light emitting functional layer of the second sub-pixel is greater than the curvature of the light emitting functional layer of the third sub-pixel.

34-35. (canceled)

36. The display panel according to claim 25, wherein one or more light shielding patterns are arranged between the color film patterns of adjacent two sub-pixels, and a partial region of the color film patterns is arranged on a side of the light shielding patterns away from the driving substrate; and
the region surrounded by the orthographic projection of the outer contour of the second groove on the driving substrate falls within an orthographic projection of the light shielding patterns on the driving substrate; or
wherein there is an overlap area between the color film patterns of adjacent two sub-pixels, and the region surrounded by the orthographic projection of the outer contour of the second groove on the driving substrate falls within an orthographic projection of the overlap area on the driving substrate.

37. (canceled)

38. The display panel according to claim 36, wherein a size of the overlap area is greater than or equal to the size of the second groove in the same direction parallel to the plane where the driving substrate is located; or
wherein a height of the color film patterns in the direction perpendicular to the plane where the driving substrate is located is greater than a width of the color film patterns in the direction parallel to the plane where the driving substrate is located,
wherein a height of the overlap area between the color film patterns of adjacent two sub-pixels in the direction perpendicular to the plane where the driving substrate is located is greater than a width of the color film patterns in the direction parallel to the plane where the driving substrate is located.

39-40. (canceled)

41. A display device, comprising the display panel according to claim 1.
